(19) United States
(12) Patent Application Publication
(10) Pub. No.: US 2025/0104966 A1
(43) Pub. Date: Mar. 27, 2025

(54) MULTI-BEAM CHARGED PARTICLE IMAGING SYSTEM WITH IMPROVED IMAGING OF SECONDARY ELECTRON BEAMLETS ON A DETECTOR

(71) Applicant: Carl Zeiss MultiSEM GmbH, Oberkochen (DE)

(72) Inventors: Stefan Schubert, Oberkochen (DE); Leonie Liebisch, Aalen (DE)

(21) Appl. No.: 18/973,902

(22) Filed: Dec. 9, 2024

Related U.S. Application Data
(63) Continuation of application No. PCT/EP2023/025226, filed on May 15, 2023.

(30) Foreign Application Priority Data
Jun. 10, 2022 (DE) 10 2022 205 902.6

(51) Int. Cl. H01J 37/317; H01J 37/147; H01J 37/21; H01J 37/244; H01J 37/26; H01J 37/28

(52) U.S. Cl. CPC H01J 37/3177; H01J 37/1474; H01J 37/21; H01J 37/244; H01J 37/265; H01J 37/28; H01J 2237/04928; H01J 2237/2448; H01J 2237/2806; H01J 2237/2817; H01J 2237/2826; H01J 2237/30488

(57) ABSTRACT

A multi-beam charged particle beam system and a method of operating a multi-beam charged particle beam system with higher precision are configured for a determination of an assignment of secondary electron focus spot to a plurality of sets of detection elements. The system and method are further configured to adjust the assignment and for a calibration of a monitoring method and system for monitoring the assignment. The system and method are applicable for an inspection of samples, for example for wafer or mask inspection.

### CROSS-REFERENCE TO RELATED APPLICATIONS

The present application is a continuation of, and claims benefit under 35 USC 120 to, international application No. PCT/EP2023/025010, filed Jan. 17, 2023, which claims benefit under 35 USC 119 of German Application No. 10 2022 205 902.6, filed Jun. 10, 2022. The entire disclosure of each of these applications is incorporated by reference herein.

### FIELD

The present disclosure relates to a multi-beam charged particle imaging system and an improved method of operation of a multi-beam charged particle imaging system. For example, the present disclosure relates to a control unit and a method for imaging of secondary electron beamlets on a detector.

### BACKGROUND

With the continuous development of ever smaller and ever more complex microstructures such as semiconductor components, there is a desire to develop and optimize planar production techniques and inspection systems for producing and inspecting small dimensions of the microstructures. By way of example, the development and production of the semiconductor components typically involves high resolution metrology tools with high throughput. The planar production techniques can involve process monitoring and process optimization for a reliable production with a high throughput. Moreover, there have been recent demands for an analysis of semiconductor wafers for reverse engineering and for a customer-specific, individual configuration of semiconductor components. Therefore, there is a desire for an inspection mechanism which can be used with a high throughput for examining the microstructures on wafers with great accuracy. Recently, multi-beam scanning electron microscopes have been introduced to support development and manufacturing of micro-electronic semiconductor components. By way of example, a multi-beam scanning electron microscope is disclosed in U.S. Pat. No. 7,244,949 B2 and in US 2019/0355544 A1. In the case of a multi-beam charged particle microscope or MSEM, a sample is irradiated simultaneously with a plurality of individual electron beams, which are arranged in a field or raster. By way of example, J=4 to J=10,000 individual electron beams can be provided as primary radiation, with each individual electron beam being separated from an adjacent individual electron beam by a pitch of 1 to 200 micrometers. By way of example, an MSEM has approximately J=100 separated individual electron beams (“beamlets”), which for example are arranged in a hexagonal raster, with the individual electron beams being separated by a pitch of approximately 10 μm. The plurality of J individual charged particle beams (primary beams) are focused on a surface of a sample to be examined by way of a common objective lens. By way of example, the sample can be a semiconductor wafer which is accommodated via a wafer chuck that is assembled on a movable stage. During the illumination of the wafer surface with the primary individual particle beams, interaction products, for example secondary electrons or backscattered electrons, emanate from the surface of the wafer. Their start points correspond to those locations on the sample on which the plurality of J primary individual particle beams are focused in each case. The amount and the energy of the interaction products depend on the material composition and the topography of the wafer surface. The interaction products form a plurality of secondary individual particle beams (secondary beams), which are collected by the common objective lens, and which are directed by a secondary electron optical imaging system at a detector arranged in an image plane. The detector comprises a plurality of detection regions, each of which comprises at least one detection element, and the detector measures an intensity distribution for each of the J secondary individual particle beams. A digital image of an image field of for example 100 μm×100 μm is obtained in the process.

The plurality of secondary beamlets is focused by the secondary electron optical imaging system and a plurality of focus points of the secondary beamlets is formed on an image plane, in which the detector is arranged. The detector generally comprises a plurality of detection elements. The number of detection elements is at least as high as the number of beamlets, such that each of the secondary beamlets is detected by at least one detection element. Typically, each secondary beamlet is assigned to a set of detection elements, by which the intensity of one corresponding secondary beamlet is detected. In an example, each secondary beamlet is assigned to a set of detection elements, wherein each set of detection elements comprises at least one, for example, four, nine or more individual detection elements. However, the initial assignment of the sets of detection elements to the raster configuration of the focus spots of the secondary electron beamlets can be subject to changes or drifts in the multi-beam charged particle microscope system. Therefore, the signal strength of collected secondary electrons can be reduced or cross talk can be increased. Cross talk is generally the effect of detection of unwanted secondary electrons by a set of detection elements, wherein unwanted secondary electrons are for example secondary electrons from other secondary electron beamlets which are not assigned to the respective set of detection elements.

In the case of scanning electron microscopes for wafer inspection, it is generally desirable to keep the imaging conditions stable such that the imaging can be carried out with great reliability, great throughput, and high repeatability. Especially throughput and repeatability are determined by a precise alignment of a focus point of secondary electron beamlets with respect to its assigned set of detection elements. Several solutions for monitoring and aligning the focus points of the secondary beamlets to the detection elements have been proposed. U.S. Pat. No. 9,702,983 B2 and U.S. Pat. No. 9,336,982 BB show a detector comprising an electron to light conversion element (i.e. a scintillator plate). The focus spots of the plurality of secondary electron beamlets are formed on the electron to light conversion element. Excited light is imaged by an optical relay system on a fiber bundle. Each fiber is connected to an individual detection element and the entrance or input ends of the fibers of the fiber bundle are corresponding to the detection elements of the detector. To monitor the alignment of the optical image of the excited light from the electron to light conversion element on the entrance or input ends of the fiber bundle, a second monitoring system is implemented. The second monitoring system of U.S. Pat. No. 9,702,983 B2 and U.S. Pat. No. 9,336,982 BB is given by an optionally retractable optical monitoring system in the optical relay system, configured to image the excited light on a high-resolution detector. Similar solutions have been proposed in US 2020124546 AA. In US 2020124546 AA, various second monitoring system are proposed, either in form of an optionally retractable optical monitoring system, or by for example a beam deflector in the secondary electron beam path, configured to guide the plurality of secondary electron beamlets on a second detector. For the solutions that have provided, however, a precise calibration of the second monitoring system, including a second detector, with respect to detection elements of the first detector is typically used. In addition, with the increasing demand on resolution and throughput of multi-beam charged particle imaging systems, a time-consuming re-calibration of the second monitoring system is repeated frequently.

US 2020/0211811 A1 discloses a multi-beam inspection apparatus with a source conversion unit. The source conversion unit can comprise a micro-structure deflector array including a plurality of multipole structures. The micro-deflector array may comprise a first multipole structure having a first radial shift from a central axis of the array and a second multipole structure having a second radial shift from the central axis of the array. The first radial shift is larger than the second radial shift, and the first multipole structure comprises a greater number of pole electrodes than the second multipole structure to reduce deflection aberrations when the plurality of multipole structures deflects a plurality of charged particle beams.

DE 10 2013 016 113 A1 discloses a detection system and a detection method for detecting a plurality of electron beams using a scintillator plate combined with a light detection system. Impingement positions at which the electron beams impinge the scintillator plate are slowly varied in order to compensate for a reduction of the quality of the scintillator plate as time progresses. The degradation of the quality of the scintillator plate can arise for example due to aging of the scintillator material or due to a deposition of residual gases on the scintillator plate.

### SUMMARY

The disclosure seeks to provide an improved multi-beam charged particle imaging system and an improved method of operation of such a system, which is configured to determine the raster configuration of the focus spots of the secondary electron beamlets on a detector with higher precision and without the need of a frequent re-calibration of a second monitoring system. The disclosure also seeks to re-adjust or to modify the assignment of the sets of detection elements to the raster configuration of the focus spots of the secondary electron beamlets. The disclosure also seeks to provide a fast and efficient method to calibrate a second monitoring system. Further, the disclosure seeks to increase the signal strength of collected secondary electrons. In addition, the disclosure seeks to increase the throughput of a multi-beam charged particle imaging system. The disclosure also seeks to reduce the effects of cross talk.

The disclosure provides a multi-beam charged particle imaging system and a method of operating such a system. The multi-beam charged particle imaging system comprises a mechanism for generating a plurality of primary charged particle beamlets. The multi-beam charged particle imaging system comprises an object irradiation system for focusing the plurality of primary charged particle beamlets on a surface of an object at a plurality of irradiation positions. During use, at each irradiation position, secondary charged particles are generated, from which a plurality of secondary beamlets is formed. The multi-beam charged particle imaging system comprises a secondary electron imaging system for focusing the plurality of secondary beamlets and for forming a plurality of focus points of the secondary beamlets in an image plane. The multi-beam charged particle imaging system further comprises a detector, arranged in the image plane. According to the disclosure, the detector comprises a plurality of sets of detection elements with one set of detection elements for each secondary electron beamlet. The plurality of sets of detection elements is arranged in a raster configuration. The setup of the secondary electron optical imaging system, the detector, and the assignment of the sets of detection elements to the focus spots of the secondary electron beamlets is initially determined and stored in a memory of the multi-beam charged particle imaging system.

Multi-beam charged particle imaging systems according to the disclosure can comprise a mechanism for generating a plurality of primary charged particle beamlets, which are arranged in a first raster configuration. At each irradiation position with a primary charged particle beamlet, secondary charged particles can be generated, which form a plurality of secondary beamlets. The origins of the plurality of secondary beamlets can therefore be arranged in a second raster configuration, which is similar to the first raster configuration of the primary charged particle beamlets. During use, focus points of the secondary beamlets can be formed in the image plane of the secondary electron imaging system in a third raster configuration. Typically, the third raster configuration can be similar to the first or second raster configuration. The set of detection elements is arranged in a fourth raster configuration, which is ideally identical to the third raster configuration. However, due to deviations or drifts during an inspection operation, the third raster configuration of focus spots of secondary electron beamlets might significantly deviate from the fourth raster configuration of the sets of detection elements. The multi-beam charged particle imaging system according to the disclosure can be configured to monitor the third raster configuration in an efficient manner, to detect deviations and to control an adjustment mechanism to maintain a minimum deviation between the focus points of the secondary electron beamlets and the fourth raster configuration of the plurality of sets of detection elements.

The multi-beam charged particle imaging system can further comprise a first deflection scanner and a scanning control unit. During an inspection mode of operation, the scanning control unit is configured to control the first deflection scanner such that the plurality of primary charged particle beamlets is scanned over the surface of a sample. Therefore, during the inspection mode of operation, a plurality of moving irradiation positions in the raster configuration is formed on the surface of a sample. During an inspection mode, the origins of the secondary beamlets are as well moving over time over the surface of the sample. The multi-beam charged particle imaging system further comprises a second deflection scanner. During an inspection mode of operation, the scanning control unit is configured to control the second deflection scanner synchronous to the first deflection scanner. During an inspection mode of operation, the scanning control unit is configured to control the second deflection scanner with a deflection amplitude adjusted such that the focus spots of the secondary electron beamlets are kept constant at the image plane of the secondary electron imaging system.

The secondary electron imaging system further of the multi-beam charged particle imaging system can comprise electron-optical lenses to change a focus plane of the focus spots of the secondary electron beamlets. Thereby, the focus spots of the secondary electron beamlets can either be focused into the image plane of the secondary electron imaging system or can be defocused.

The multi-beam charged particle imaging system can further comprise an operation control unit, configured for determining the assignment of the sets of detection elements to the third raster configuration of the focus spots of the secondary electron beamlets, for example during an adjustment and calibration operation of the multi-beam particle imaging system. Thereby, a magnification or scale, a displacement, or a rotation between the third raster configuration and the fourth raster configuration is adjusted. The setup of the secondary electron optical imaging system and the detector is stored in a memory of the operation control unit.

According to a first embodiment of the disclosure, a multi-beam charged particle imaging system is provided which is configured for a monitoring operation. The multi-beam charged particle imaging system is configured for determining the third raster configuration of the focus spots of the secondary electron beamlets. During the monitoring operation, a scanning control unit of the multi-beam charged particle imaging system is configured to jointly scan the focus spots of the secondary electron beamlets over the image plane of the secondary electron imaging system. The multi-beam charged particle imaging system further comprises a monitoring data acquisition system, which is configured to record a scanning intensity signal for each secondary electron beamlet in dependence of the scanning coordinates (p,q) controlled by the scanning control unit. Scanning is achieved by at least one common scanning deflector, which is configured and controlled to deflect the plurality of primary charged particle or secondary electron beamlets sequentially, such that each secondary electron beamlet is focused on different relative scanning coordinates (p,q) in the image plane of the secondary electron imaging system. The temporal sequence of intensity signals is transformed by the monitoring data acquisition system into a spatial order of relative scanning coordinates (p,q) of the secondary electron beamlets in the image plane. During the monitoring operation, the monitoring data acquisition system is configured to determine the relative lateral position of each focus spot of each secondary beamlet to an assigned set of detection elements.

The plurality of scanning intensity signals, comprising a scanning intensity signal for each secondary electron beamlet, is temporally stored in a memory of the monitoring data acquisition system. In an example, the monitoring data acquisition system is further configured to determine the relative position of the focus spots of the secondary electron beamlets within each scanning intensity signal. In an example, the relative position of a focus spot is determined at the scanning position with a maximum intensity signal. Other examples include an assessment of the scanning intensity signal by image processing and pattern recognition techniques. Such methods may include matching filter techniques or machine learning techniques. The relative positions of each focus spot of the secondary electron beamlets are temporally stored in a memory of the monitoring data acquisition system. The multi-beam charged particle imaging system is further configured to determine a deviation of the third raster configuration of the focus spots of the secondary electron beamlets relative to the fourth raster configuration of the sets of detection elements.

According to the first embodiment, the monitoring data acquisition system can be configured to record a scanning intensity signal for each set of detection elements in dependence of the scanning coordinates (p,q). In an example, different scanning ranges of scanning coordinates (p,q) can be selected. In an example, a large scanning range is selected such that a secondary electron beamlet is scanned not only over one assigned set of detection elements, but also over neighboring sets of detection elements. In this example, each scanning intensity signal comprises the intensity signals of several focus spots of several secondary electron beamlets scanned over one set of detection elements. During the monitoring operation, the monitoring data acquisition system is configured to determine the relative position of a selected focus spot of a selected secondary beamlet in a scanning intensity signal. During the monitoring operation, the monitoring data acquisition system is further configured to determine the relative position of other focus spot of adjacent secondary beamlets in a scanning intensity signal. Thereby, for example a rotation between the third raster configuration and the fourth raster configuration can be determined with high precision.

According to the first embodiment of the disclosure, the multi-beam charged particle imaging system can be configured to determine the third raster configuration of the focus spots of the secondary electron beamlets, and to determine a deviation between the third raster configuration of the focus spots of the secondary electron beamlets and the fourth raster configuration of the sets of detection elements. In a further example, the monitoring operation can be configured for a monitoring of the assignment of the sets of detection elements with respect to the third raster configuration of the focus spots of the secondary electron beamlets.

In an example, the configuration of the multi-beam charged particle imaging system is not limited to the determination of the lateral positions of the focus spots of the secondary electron beamlets. In an example, the multi-beam charged particle imaging system is configured for the determination of the propagation angle of each secondary electron beamlet. The mean propagation angles of each of the secondary electron beamlets are also described as the telecentricity property of the secondary electron beamlets. In this example, the scanning control unit is configured to jointly scan the focus spots of the secondary electron beamlets perpendicular to the image plane of the secondary electron imaging system. A scanning operation perpendicular to the image plane is achieved by controlling at least an electro-optical element configured to adjust the focus plane of the secondary electron beamlets. By continuously changing the focus plane, a propagation angle of a secondary beamlet is transferred to a lateral displacement of an intersection position of respective secondary beamlet with the image plane. The multi-beam charged particle imaging system according to the first embodiment is configured to determine the lateral positions of the focus spots of the secondary electron beamlets within the image plane and can therefore as well be applied to determine the telecentricity property of the secondary electron beamlets.

According to a second embodiment of the disclosure, the multi-beam charged particle imaging system is configured to determine a deviation between the third raster configuration and the fourth raster configuration and is configured to adjust either the third or fourth raster configuration to minimize the deviation. Thereby, during an inspection mode of operation, the differences between the third and fourth raster configurations are kept below a predetermined threshold. The multi-beam charged particle imaging system according to the second embodiment comprises an adjustment mechanism for adjusting the third or fourth or both raster configurations. The adjustment mechanism are configured to adjust the third raster configuration or the fourth raster configuration or both such that an overlap of a focus point of each secondary beamlet with an assigned set of detection elements is maximized. Thereby, a maximum signal strength of secondary electron signals is achieved, and throughput can be increased, and cross talk is reduced to a minimum.

The adjustment mechanism can comprise at least one of the following: a) elements of the secondary electron optical imaging system, b) an adjustment or a rotation mechanism of the detector, c) an optical mechanism of an optical relay system within the detector, or d) a detector with a plurality of detection elements and a control unit configured to change the assignment of detection elements to the plurality of sets of detection elements. In a further example, the adjustment mechanism further comprise a mechanism to adjust a telecentricity property of the secondary electron beamlets.

The multi-beam charged particle imaging system can further comprise a control unit configured to determine a deviation between the third raster configuration of the focus spots of the secondary electron beamlets and the fourth raster configuration of the sets of detection elements. In an example, the determination is including the determination of a telecentricity property of the secondary electron beamlets. The control unit can be further configured to derive at least one control signal from the deviation and to provide the at least one control signal during use to at least one adjustment mechanism.

In an example, the control unit is configured to analyze the deviation and to derive at least one of several deviation components. Deviation components comprise for example a displacement, a difference in scale, a rotation, or a distortion between the third and fourth raster configuration. In an example, the deviation components further comprise a deviation from a perfect telecentricity property. However, also other deviation components can be derived. The deviation components can individually be assigned to an adjustment mechanism, configured for compensating the respective deviation components.

In a first example, the secondary electron optical imaging system of the multi-beam charged particle imaging system comprises an electron-optical mechanism to adjust a magnification, a deflection, a rotation, or a telecentricity property of the plurality of secondary electron beamlets. For example, the secondary electron optical imaging system can comprise at least two electron-optical imaging lenses of variable optical power to adjust a magnification of the plurality of secondary electron beamlets. For example, the secondary electron optical imaging system can comprise at least one deflector to adjust a displacement of the plurality of secondary electron beamlets. For example, the secondary electron optical imaging system can comprise at least one magnetic lens of variable optical power to adjust a rotation of the plurality of secondary electron beamlets. For example, the secondary electron optical imaging system can comprise at least one magnetic lens of variable optical power to adjust an azimuthal telecentricity component of the plurality of secondary electron beamlets.

In a second example, the detector comprises a mechanical mechanism to adjust a displacement or a rotation of the sets of detections elements. For example, the detector or components of the detector can be mounted on an actuated stage configured for a lateral adjustment and rotation of the position of the detector or the detection elements of the detector.

In a third example, the detector comprises an optical mechanism to adjust a magnification or a displacement or a rotation. The detector of the third example comprises an optical relay system for imaging and guiding the excited light from the electron-to-light conversion element to light detection elements. For that purpose, the optical relay system can comprise a zoom lens systems, mirrors, image-rotating prisms, and fibers.

In a fourth example, the detector comprises a plurality of individual detection elements and control mechanisms to modify the assignment of the plurality of individual detection elements to the plurality of sets of detections elements. Thereby, the fourth raster configuration, formed by the modified sets of detections elements, is adjusted to the third raster configuration of the focus spots of the secondary electron beamlets.

With at least one of the adjustment mechanisms or any combination thereof, for example a deviation in magnification or scale, a displacement, or a rotation between the third raster configuration and the fourth raster configuration is adjusted. With at least one of the adjustment mechanisms or any combination thereof, for example a deviation in the propagation angles of the secondary electron beamlets is reduced, and an almost perfect telecentricity property is achieved.

In an example, the control unit of the multi-beam charged particle imaging system is configured to frequently switch during operation from an inspection mode of operation to a monitoring mode of operation and to frequently determine a deviation between the third raster configuration and the fourth raster configuration. The multi-beam charged particle imaging system is further configured to frequently adjust the adjustment mechanism to minimize the deviation between the third and fourth raster configuration. Thereby, maximum signal strength, minimal noise and highest imaging precision is continuously maintained during an inspection mode of operation. The control unit of the multi-beam charged particle imaging system can for example be configured to switch to a monitoring mode of operation between two inspection sites of an object, or between the exchange of a first object with a second object for inspection.

According to a third embodiment of the disclosure, a monitoring method is provided to determine a deviation between a third raster configuration of focus spots of a plurality of secondary electron beamlets and a fourth raster configuration of a plurality of sets of detection elements. According to the third embodiment, the focus spots of the secondary electron beamlets are jointly scanned over an image plane, in which a detector is arranged. An intensity signal is recorded for each secondary electron beamlet in dependence of the scanning position of the focus spot of the secondary electron beamlet. The intensity signal corresponds to the signal collected by a set of detection elements, which is assigned to a secondary electron beamlet. The relative position of each secondary beamlet to the assigned set of detection elements is determined. The relative position can for example be determined according to the scanning position of the maximum intensity signal. Other examples include an assessment of the scanning intensity signal by image processing and pattern recognition techniques. Such methods may include matching filter techniques or machine learning techniques. Thereby, a deviation between the third raster configuration of the focus spots of the secondary electron beamlets and the fourth raster configuration of the sets of detection elements is determined.

An example of method of operating a multi-beam charged particle system according to the third embodiment comprises a scanning deflection of the plurality of primary charged particle beamlets with a first deflection scanner over a surface of a sample. During operation, a plurality of moving irradiation positions in a raster configuration is formed on the surface of the sample. The moving irradiation positions are forming a plurality of origins of the secondary beamlets. During operation, the origins of the secondary beamlets are as well performing a scanning movement over the surface of the sample. A method of operating a multi-beam charged particle system comprises a scanning deflection of the plurality of secondary charged particle beamlets with a second scanning deflector. In an inspection mode of operation, the scanning deflection of the plurality of secondary charged particle beamlets is controlled to compensate the scanning movement of the origins of the secondary beamlets, such that each focus point of each secondary beamlet is kept at a position within its assigned set of detection elements. During a method of inspection, the second deflection scanner is synchronously operated with the first deflection scanner, with a deflection amplitude adjusted such that the focus spots of the secondary electron beamlets are kept constant at the image plane of a secondary electron imaging system.

In the monitoring mode of operation according to the third embodiment, the scanning deflection of the plurality of first or secondary charged particle beamlets is controlled to cause a scanning movement of the focus spots of the secondary electron beamlets in the image plane of the secondary electron imaging system. According to the third embodiment, the method of monitoring operation comprises a control of at least one of the first and second deflection scanner such that the focus points of the secondary electron beamlets is scanned in the image plane of the secondary electron imaging system. In an example, the first deflection scanner is set in an off mode of operation, and the secondary electron beamlets are scanning deflected by the second deflection scanner. In an example, the second deflection scanner is set in an off mode of operation, and the scanning movement of the origins of the secondary electron beamlets is not compensated.

In an example, both first and second deflection scanners are controlled in an unsynchronized operation, such that a residual scanning movement of the focus points of the secondary electron beamlets in the image plane is achieved.

According to the third embodiment, the method is configured such that each focus point of the secondary beamlets is scanned over an assigned set of detection elements, and a plurality of scanning image data or scanning intensity signals is recorded over the scanning time and assigned to corresponding scanning coordinates (p,q).

For example, an overlap signal of each focus spot with a set of detection elements is determined, and a maximum signal strength is determined from an optimal overlapping scanning position coordinate of each focus point with the assigned set of detection elements. The scanning range or scanning amplitude of the secondary beamlets can be adjusted to scan over at least one set of detection elements, for example three sets of detection elements. Thereby, a rotation between the third and fourth raster configuration can be determined with high precision.

In an example, the monitoring method is not limited to the determination of the lateral positions of the focus spots of the secondary electron beamlets. In an example, the monitoring method is configured for the determination of the propagation angle of each secondary electron beamlet. In this example, the monitoring method comprises the step of jointly scanning the focus plane of the focus spots of the secondary electron beamlets perpendicular to the image plane of the secondary electron imaging system. The scanning perpendicular to the image plane is achieved by changing the focus plane of the secondary electron beamlets by at least an electro-optical element of the secondary electron imaging system. By continuously scanning the focus plane through the image plane, a propagation angle of a secondary beamlet is transferred to a lateral displacement of an intersection position of that secondary beamlet in the image plane. The monitoring operation according to the third embodiment can therefore comprise the steps of determining the lateral positions of the focus spots of the secondary electron beamlets within the image plane, and the steps of determining the propagation angle of a secondary electron beamlet. From the propagation angles of each secondary electron beamlet, a telecentricity property of the plurality of secondary electron beamlets is determined.

According to the fourth embodiment of the disclosure, the deviation determined according to the third embodiment is utilized to control a set of adjustment mechanisms. The set of adjustment mechanisms of the multi-beam charged particle imaging system are configured to adjust the third raster configuration or the fourth raster configuration or both such that an overlap of each secondary beamlet with a set of detection elements is maximized. Thereby, an optimum signal strength of secondary electrons is achieved, and a cross talk is reduced to a minimum. According to an example of the fourth embodiment, the deviation is analyzed, and at least one of several deviation components is derived. Deviation components comprise for example a displacement, a difference in scale, a rotation, or a distortion between the third and fourth raster configuration. The deviation components can individually be assigned to an adjustment mechanism. The deviation can also comprise deviations components of a deviation from a perfect telecentricity of the plurality of secondary electron beamlets. The adjustment mechanism can comprise a mechanism to adjust a telecentricity property of the secondary beamlets. The telecentricity property of the secondary beamlets can be adjusted to achieve a perfect telecentricity of secondary beamlets. Thereby, an optimum signal strength of secondary electrons is achieved even if the focus spots of the secondary electron beamlets are not formed in the image plane, for example due to a topography of a sample or charging effects of the sample.

According to the fifth embodiment of the disclosure, a method of calibrating a second monitoring system is provided. According to the fifth embodiment, a multi-beam charged particle system comprises a second monitoring system. In an example, the second monitoring system is given by an optionally retractable monitoring system, configured to image the focus spots of the secondary electron beamlets on a high-resolution detector. In a further example, the second monitoring system is given by an optionally retractable optical monitoring system in the optical relay system of a detector. Various other second monitoring system are possible, for example a beam deflector in the secondary electron beam path, configured to alternatively guide the plurality of secondary electron beamlets on a second detector. According to the fifth embodiment, a method of calibrating a second monitoring system is provided. The second monitoring system is including a second detector. With the apparatus and methods according to the first to fourth embodiments, a raster configuration and a telecentricity property of a plurality of secondary electron beamlets can be determined. The raster configuration and telecentricity property can be adjusted by an adjustments mechanism, and the second monitoring system can be calibrated with the determined or adjusted raster configuration and telecentricity property. Thereby, a precise calibration of the second monitoring system is possible. The calibration of the second monitoring system according to the fifth embodiment can frequently or automatically be repeated without supervised interaction. Thereby, during an inspection operation, a monitoring with high precision can be maintained and the signal strength and performance of an inspection operation can be maintained at an optimized level.

In the context of the disclosure, a raster configuration is an arrangement of elements (here: focus positions of primary or secondary beamlets) in a regular raster grid, for example a hexagonal raster grid, at predefined relative distances between the plurality of elements. The absolute size or scale and the rotation of the raster configuration can however be different at different positions within the multi-beam charged particle imaging system. Typical raster configurations comprise for example more than 60, more than 90 or even more than 300 primary beamlets, arranged in a hexagonal or rectangular raster. Other raster configurations are circular raster configurations, in which a plurality of beamlets is arranged on at least one circular ring.

The disclosure is not restricted to the specific embodiments and examples, but variations of the embodiments are also possible. Although in principle reference is made to a wafer as an object, the disclosure is also applicable to other objects as used in semiconductor manufacturing. By way of example, the object can also be a mask, for example a mask for EUV lithography, rather than a semiconductor wafer. In contrast to semiconductor wafers, such masks are generally rectangular and have a significantly greater thickness. The disclosure is however not limited to objects as used in semiconductor manufacturing, but is also applicable to general objects, including for example mineral probes or tissue. The disclosure is further described at the example of a multi-beam system having a plurality of primary electron beamlets, but other charged particles, for example helium ions, may also be used.

The described embodiments of the disclosure can be combined with one another in full or in part, provided that no technical contradictions arise as a result. It is self-evident that a person skilled in the art considers obvious variations of the exemplary embodiments to be possible and not excluded in the description.

### BRIEF DESCRIPTION OF THE DRAWINGS

The disclosure will be understood even better with reference to the accompanying figures.

FIG. 1 shows a multi-beam imaging system according to the first embodiment and second embodiment.

FIGS. 2A-2D illustrate raster configurations at the multi-beam forming unit, the object plane, the image plane, and the sets of detection elements.

FIGS. 3A-3B illustrate a detector with a plurality of sets of detection elements and with focus spots of secondary electron beamlets.

FIG. 4 illustrates a set of detection elements comprising a plurality of individual detection elements.

FIGS. 5A-5F illustrate examples of scanning intensity distributions of one set of detection elements after scanning of the secondary electron beamlets.

FIGS. 6A-6D show an illustration of some typical deviations of the third raster configuration.

FIG. 7 shows an example of a detector for secondary electron beamlets.

FIGS. 8A-8B illustrate a re-assignment of detection elements to modified sets of detection elements.

FIG. 9 shows a method according to the third and fourth embodiment of the disclosure.

FIG. 10 shows an example of a determination of deviation components

FIG. 11 shows a calibration method for calibrating a monitoring system

FIG. 12 illustrates of a multi-beam imaging system with a secondary electron monitoring system.

### DETAILED DESCRIPTION

Below, the same reference signs denote the same features, even if these are not explicitly mentioned in the text.

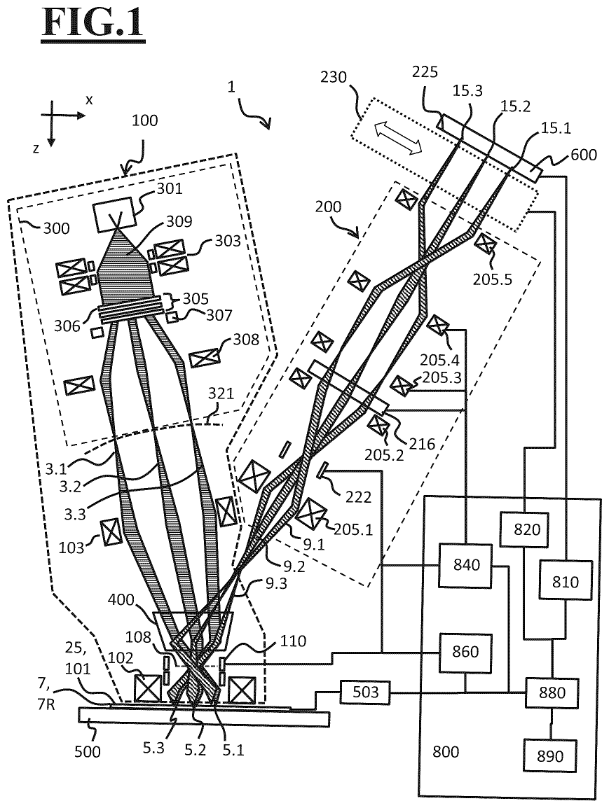

FIG. 1 is a schematic illustration of a multi-beam charged particle imaging system 1 (in short also multi-beam system 1) according to the first embodiment of the disclosure. The multi-beam system 1 uses a plurality of charged particle beams for forming an image of an object 7. The multi-beam system 1 generates a plurality of J primary particle beams 3 which strike the object 7 to be examined in order to generate interaction products, e.g. secondary electrons, which emanate from the object 7 and are subsequently detected. The multi-beam system 1 is of the scanning electron microscope (SEM) type, which uses a plurality of primary electron beams 3 which are incident on a surface of the object 7 at a plurality of locations and generate there a plurality of primary electron beam focus spots 5, that are spatially separated from one another. The object 7 to be examined can be of any desired type, e.g., a semiconductor wafer or a semiconductor mask, and can comprise an arrangement of miniaturized elements. The surface 25 of the object 7 is arranged in an object plane 101 of an objective lens 102 of an illumination system 100. The object 7 can be a wafer or a semiconductor mask or a reference object 7R with for example a regular microscopic pattern structure 27 (not shown).

A diameter of the minimal beam spots or focus spots 5 shaped in the object plane 101 can be small. Exemplary values of this diameter are below 4 nanometers, for example 3 nm or less. The focusing of the primary charged particle beamlets 3 for shaping the focus spots 5 is carried out by the objective lens system 102. In this case, the objective lens system 102 can comprise a magnetic immersion lens. Further examples of focusing mechanisms are described in the German patent DE 102020125534 B3, the entire content of which is herewith incorporated in the disclosure.

The plurality of focus spots 5 of the primary beams form a regular raster arrangement of incidence locations, which are formed in the object plane 101. The number J of beamlets primary beamlets may be five, twenty-five, or more. In practice, the number of beamlets J, and hence the number of incidence locations or focus spots 5, can be chosen to be significantly greater, such as, for example, J=10×10, J=20×30 or J=100×100. Exemplary values of the pitch P2 between the incidence locations are 1 micrometer, 10 micrometers, or more, for example 40 micrometers. For sake of simplicity, only three primary beamlets 3.1, 3.2 and 3.3 with corresponding focus points 5.1, 5.2 and 5.3 are shown in FIG. 1.

The primary particles 3 striking the object 7 generate interaction products, e.g. secondary electrons, back-scattered electrons or primary particles that have experienced a reversal of movement for other reasons, which emanate from the surface of the object 7. The interaction products emanating from the surface of the object 7 are shaped by the objective lens 102 to form secondary electron beamlets 9. For sake of simplicity, through the disclosure, all the interaction products are collectively described as secondary electrons, forming secondary electron beamlets 9.

The multi-beam system 1 provides a detection beam path for guiding the plurality of secondary particle beamlets 9 to a secondary electron imaging system 200. The secondary electron imaging system 200 comprises several electron-optical lenses 205.1 to 205.5 for directing the secondary particle beams 9 towards a spatially resolving particle detector 600. The detector 600 is arranged in the image plane 225. The detector 600 comprises a plurality of detection elements. Detection elements can for example be diodes such as PMDs, or CMOS detection elements, provided with electron-to-light conversion elements, or can be formed as direct electron detection elements.

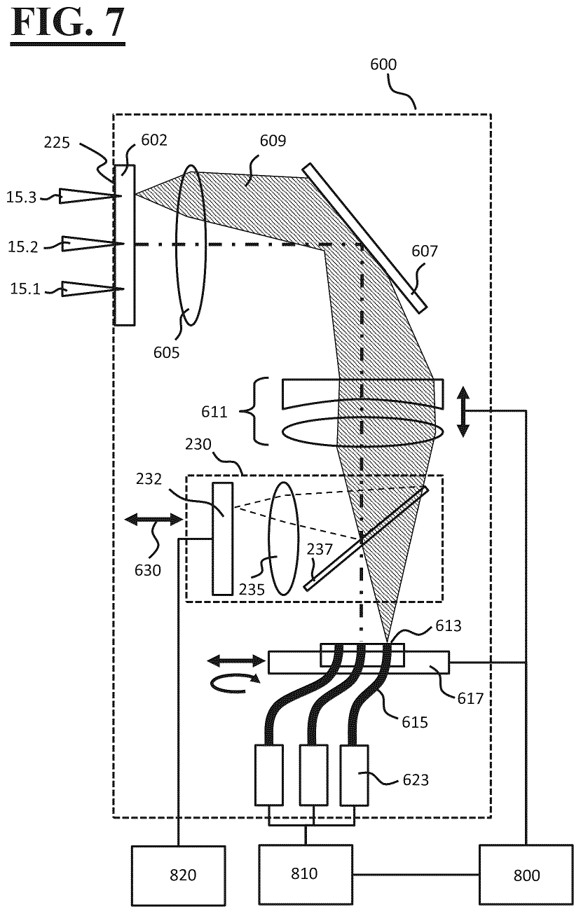

In an example, the detector 600 comprises an electron-to-light conversion element, such as a scintillator plate, by which secondary electrons are converted into light, and a plurality of light detection elements. The combination of the electron-to-light conversion element and the plurality of light detection elements hereby form together a plurality of electron detection elements. A further example of a detector is described below at the example of FIG. 7.

The imaging with the secondary electron imaging system 200 is strongly magnifying such that both the raster pitch of the primary beams on the wafer surface and the size and shape of focal points of the primary beams are imaged in much magnified fashion. By way of example, a magnification is between 100× and 300× such that one nm on the wafer surface is imaged enlarged to between 100 nm and 300 nm. In the process, an image field of a multi-beam system with for example 100 μm diameter is enlarged to approximately 30 mm.

The primary particle beams 3 are generated in a beam generation apparatus 300 comprising at least one particle source 301 (e.g. an electron source), at least one collimation lens 303, a multi-aperture arrangement 305 and a first field lens 307 and a second field lens 308. The particle source 301 generates at least one diverging particle beam 309, which is at least substantially collimated by the at least one collimation lens 303, and which illuminates the multi-aperture arrangement 305. The multi-aperture arrangement 305 comprises least one first multi-aperture plate 306, which has a plurality of J openings formed therein in a first raster arrangement. Particles of the illuminating particle beam 309 pass through the J apertures or openings of the first multi-aperture plate 306 and form the plurality J of primary beamlets 3. Particles of the illuminating beam 309 which strike the first aperture plate 306 are absorbed by the latter and do not contribute to the formation of the primary beamlets 3. A multi-aperture arrangement 305 usually has at least a further multi-aperture plate, for example a lens array, a stigmator array or an array of deflection elements.

Together with the field lens 307 and a second field lens 308, the multi-aperture arrangement 305 focuses each of the primary beamlets 3 in such a way that focal points are formed in an intermediate image surface 321. Alternatively, the beam foci and the intermediate image surface 321 can be virtual. The intermediate image surface 321 can be curved to pre-compensate a field curvature of the imaging system arranged downstream of the intermediate image surface 321.

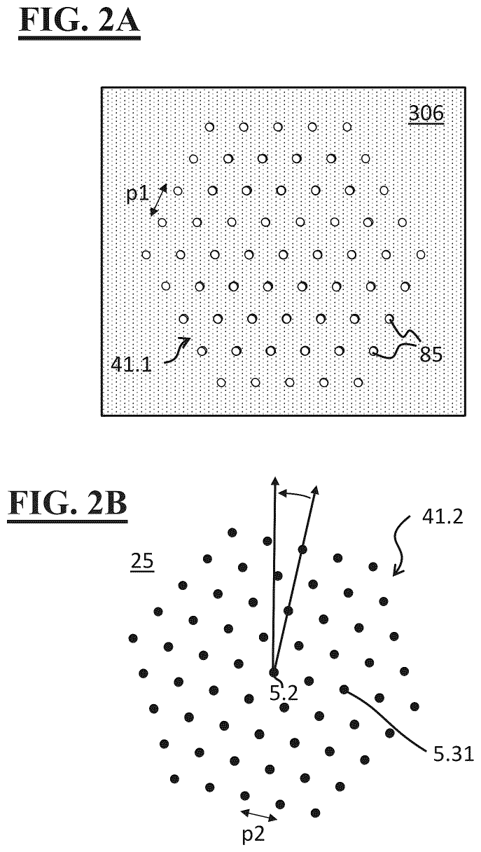

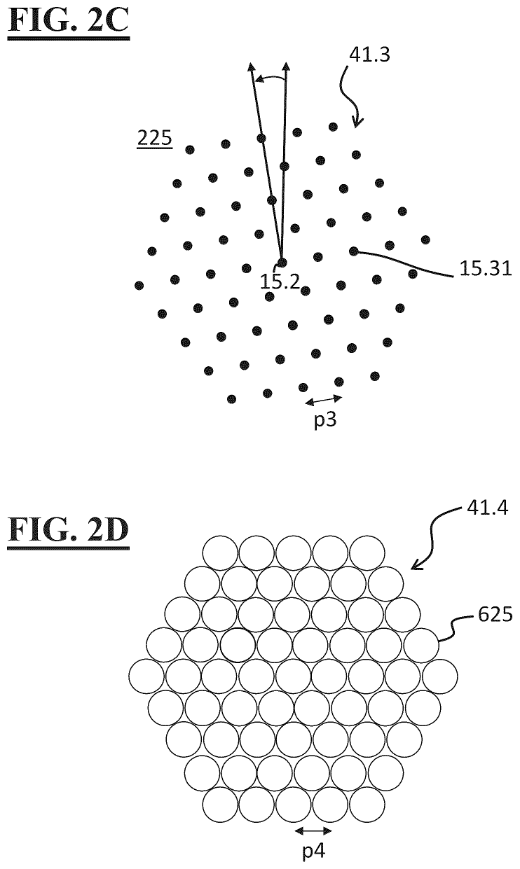

The at least one field lens 103 and the objective lens 102 provide a first imaging particle optical unit for imaging the surface 321, in which the beam foci are formed, onto the object plane 101 such that a second raster configuration of focus spots 5 of the primary beamlets is formed there. Typically, the surface 25 of the object 7 is arranged in the object plane 101, and the focal points 5 are correspondingly formed on the object surface 25 (see also FIGS. 2A-2D). The plurality of primary beamlets 3 form a crossover point 108, in the vicinity of which a first scanning deflector 110 is arranged. The first scanning deflector 110 is used to deflect the plurality of primary beamlets 3 collectively and synchronously such that the plurality of focus spots 5 are moved simultaneously over the surface 25 of the object 7. The first scanning deflector 110 is driven by a scanning control unit 860 such that in an inspection mode of operation, a plurality of two-dimensional image data of the surface are acquired. Additionally, the multi-beam system 1 can comprise further static deflectors configured to adjust the position of the plurality of the primary beamlets 3.

The objective lens 102 and the projection lenses 205 provide a secondary electron imaging system 200 for imaging the object plane 101 onto the detection plane 225. The objective lens 102 is thus a lens or a lens system that is part of both the first and the second particle optical unit, while the field lenses 103, 307 and 308 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary electron beamlets 9 transmit during use the first deflection scanner 110 in opposite direction and the scanning movement of the secondary beamlets 9 is partially compensated. The secondary electrons have typically a different kinetic energy compared to the primary electrons. Therefore, the scanning movement of the moving irradiation positions is only partially compensated. To fully compensate the scanning movement of the secondary electron beamlets 9, the second deflection scanner 222 is arranged in the secondary electron beam path. The secondary electron imaging system 200 comprises the second, collective beam deflector 222 which is arranged in the vicinity of a crossover point of the secondary electron beamlets 9. The second, collective beam deflector 222 is operated synchronously with the first beam deflector 110 and compensates during use a beam deflection of the secondary electron beamlets 9 such that the focus points 15 of the secondary beamlets 9 remain at constant position on the detection plane 225. Thereby, each focus points 15 of each individual secondary beamlet 9 is kept within the area of a set of detection elements, which is assigned to the individual secondary beamlet 9.

The secondary electron imaging system 200 comprises electron-optical lenses 205.1 to 205.5 to adjust a focus plane of the focus spots 15 of the secondary electron beamlets 9. The electron-optical lenses 205.1 to 205.5 are shown as magneto-optical elements but are not limited to magneto-optical elements and can comprise also electro-static lens elements or stigmators. With the electron-optical lenses 205.1 to 205.5, the focus spots 15 of the secondary electron beamlets 9 can be focused into the image plane 225 of the secondary electron imaging system 200. The secondary electron imaging system 200 comprises a plurality of further components, for example at least one of a multi-aperture array element, a deflector or an exchangeable aperture stop. Together with the objective lens 102, the lenses serve to focus the secondary beams 9 on the spatially resolving detector 600 and, in the process, compensate the imaging scale and the twist of the plurality of secondary electron beamlets 9 as a result of a magnetic lens such that a third raster arrangement of the focal points 15 of the plurality of secondary electron beamlets 9 remains constant on the detector plane 225. For example, a first and second magnetic lenses 205.4 and 205.4 are designed in reversed order to one another and have oppositely directed magnetic fields. A Larmor rotation of the secondary electron beamlets 9 can be compensated by suitably driving the magnetic lenses 205.4 and 205.5. The secondary electron imaging system 200 has further correction elements available, for example a multi-aperture plate 216.

Further information relating to such multi-beam particle beam systems and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The multi-beam charged particle imaging system 1 furthermore comprises a control system 800 configured both for controlling the individual particle optical components of the multiple particle beam system and for evaluating and analyzing the signals obtained by the detector 600. In this case, the control or controller system 800 can be constructed from a plurality of individual computers or components. By way of example, the control unit 800 comprises a control processor 880 and a control module 840 for the control of the electron-optical elements of the secondary electron imaging system 200 and the object irradiation system 100. The control unit 800 is further connected to a control module 503 for supplying a voltage to the sample 7, the voltage also being referred to as extraction voltage. Thereby, during use, an extraction field is generated between the objective 102 and the surface 25 of the object 7. During use, the extraction field decelerates the primary charged particles of the primary beamlets 3 before the sample surface 25 is reached and generates an additional focusing effect on the plurality of primary beamlets 3. At the same time, the extraction field serves during use to accelerate the secondary particles out of the surface 25 of the object 7.

Further, the control unit 800 comprises the scanning control module 860. During an inspection mode of operation, a plurality of focus points 15 of secondary electron beamlets is formed in the detection plane 225, and a plurality of signals is recorded during scanning operation of the primary beamlets 3 over the surface 25 of the sample 7. According to the disclosure, the detector 600 comprises a plurality of sets of detection elements with one set of detection elements for each secondary electron beamlet 9. During use, each set of detection elements is configured to record the intensity signal of the assigned secondary electron beamlet 9. The plurality of intensity signals for the plurality of secondary electron beamlets 9 is transferred to the image data acquisition unit 810, where the image data is processed and stored in memory 890. The sets of detection elements are arranged in a fourth raster configuration. The setup of the secondary electron optical imaging system 200, the detector 600, and the assignment of the sets of detection elements to the focus spots 15 of the secondary electron beamlets 9 is initially determined and stored in the memory 890 of the control unit 800 of the multi-beam charged particle imaging system 1.

According to the example of FIG. 1, the multi-beam charged particle imaging system 1 further comprises a retractable monitoring system 230, which can be inserted into the secondary electron beam path in front of the detection plane 225. The monitoring system 230 comprises further imaging elements and a high-resolution detector, comprising a large number of detection elements. The monitoring system 230 is connected to a monitoring control unit 820.

A multi-beam charged particle imaging system 1 according to the first embodiment comprise a mechanism for generating a plurality of primary charged particle beamlets 3, which are arranged in a first raster configuration. An example of the first raster configuration 41.1 is illustrated in FIG. 2A. FIG. 2A shows the first multi aperture plate 306 with a plurality of apertures 85 in the first raster configuration 41.1. In this example, the first raster configuration 41.1 is a hexagonal raster with a raster pitch p1 of for example 100 μm.

FIG. 2B shows the origins of the secondary electron beamlets 9, formed by the focus spots 5 of the primary beamlets 3. At each irradiation position of a surface 25 of an object 7 with a primary charged particle beamlet 3, secondary electrons are generated, which form the plurality of secondary beamlets 9. The origins of the plurality of secondary beamlets 9 are therefore arranged in a second raster configuration 41.2, which is similar to the first raster configuration 41.1 of the primary charged particle beamlets 3. The second raster configuration 41.2 can be rotated with respect to the first raster configuration 41.1 and can have a different pitch of for example p2=10 μm.

FIG. 2C shows the focus points 15 of the secondary beamlets 9 in the image plane 225. During use, focus points 15 of the secondary beamlets 9 are formed in the image plane 225 of the secondary electron imaging system 200 in a third raster configuration 41.3. The third raster configuration 41.3 can be rotated with respect to the first and second raster configurations 41.1 and 41.2 and can have a third pitch of p3=1000 μm. The plurality of sets of detection elements 625 is arranged in a fourth raster configuration 41.4 (see FIG. 2D), which is ideally identical to the third raster configuration, i.e. with identical raster pitch p4=p3 and identical rotation angle. However, due to deviations or drifts during an inspection operation, the third raster configuration 41.3 of focus spots 15 of secondary electron beamlets 9 might significantly deviate from the fourth raster configuration 41.4 of the sets of detection elements 625. Typically, the raster configurations are similar to each other. With the term “similar”, here a similarity according to the mathematical definition is used. “Similar” thus a mechanism related to each other by a scale transformation, a translation, a reflection, or by a rotation.

The multi-beam charged particle imaging system 1 according to the first embodiment comprises the first deflection scanner 110, connected to the scanning control unit 860. During an inspection mode of operation, the scanning control unit 860 is configured to control the first deflection scanner 110 such that the plurality of primary charged particle beamlets 3 is scanned over the surface of a sample 7. Therefore, during the inspection mode of operation, a plurality of moving irradiation positions in a second raster configuration is formed on the surface of a sample 7. During an inspection mode, the origins of the secondary beamlets 9 are as well moving over time over the surface of the sample 7. The multi-beam charged particle imaging system 1 further comprises the second deflection scanner 222. During an inspection mode of operation, the scanning control unit 860 is configured to control the second deflection scanner 222 synchronous to the first deflection scanner 110. During an inspection mode of operation, the scanning control unit 860 is configured to control the second deflection scanner 222 with a deflection amplitude adjusted such that the focus spots 15 of the secondary electron beamlets 9 are kept within constant areas in the image plane 225 of the secondary electron imaging system 200. The constant areas correspond to areas formed by the sets of detection elements.

The multi-beam charged particle imaging system 1 according to the first embodiment further comprise an operation control unit 800, configured for performing a monitoring operation. During a monitoring operation, the operation control unit 800 is configured for determining the assignment of the sets of detection elements 625 with respect to the third raster configuration 41.3 of the focus spots 15 of the secondary electron beamlets 9.

Thereby, a magnification or scale, a displacement, or a rotation between the third raster configuration 41.3 and the fourth raster configuration 41.4 is determined and the setup of the secondary electron optical imaging system 200 and the detector 600 is stored in the memory 890 of the control unit 800.

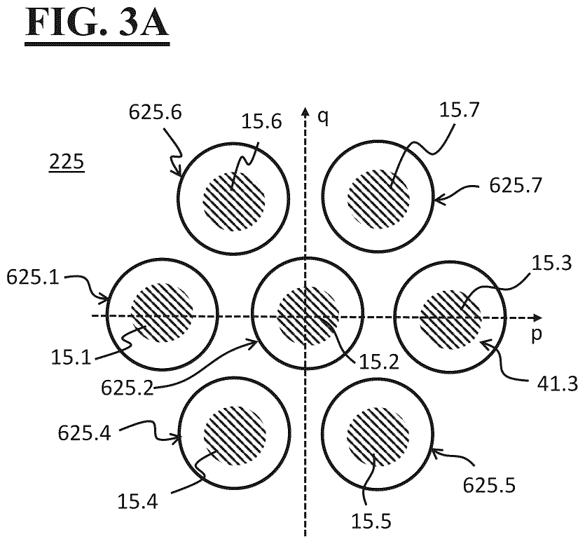

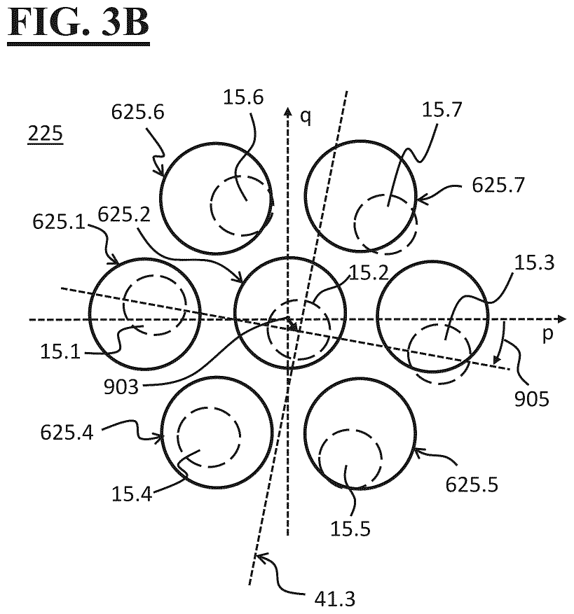

According to the first embodiment of the disclosure, the multi-beam charged particle imaging system 1 is configured for determining the third raster configuration 41.3 of the focus spots 15 of the secondary electron beamlets 9. During the monitoring operation, the scanning control unit 860 is configured to jointly scan the focus spots 15 of the secondary electron beamlets 9 over the image plane 225 of the secondary electron imaging system 200. The multi-beam charged particle imaging system 1 further comprises an image data acquisition system 810, which is configured to record a scanning intensity signal 901 for each secondary electron beamlet 9 in dependence of the scanning coordinates (p,q) controlled by the scanning control unit 860. FIG. 3A illustrates an example of a third raster configuration 41.3 of focus spots 15.1 to 15.7 in perfect alignment with a fourth raster configuration 41.4 of sets of detection elements 625.1 to 625.7 in the image plane 225. The scanning coordinates p and q are illustrated by scanning coordinate system of the central focus spot 15.2. FIG. 3B illustrates an example of a third raster configuration 41.3, which is rotated by rotation angle 905 and displaced by displacement vector 903 with respect to the fourth raster configuration 41.4. The scanning coordinates p and q are again illustrated by scanning coordinate system of the central focus spot 15.2. In this example, a hexagonal raster configuration 41.3 is shown, while only seven focus spots 15.1 to 15.7 of secondary electron beamlets 9 are shown. To each beamlet 9, a set of detection elements 625.1 to 625.7 is assigned. For example, focus point 15.2 is assigned to set of detection elements 625.2. Between the sets of detection elements 625, gaps are formed. However, it is also possible that no gaps are formed, and for example further detection elements are arranged between the detection elements.

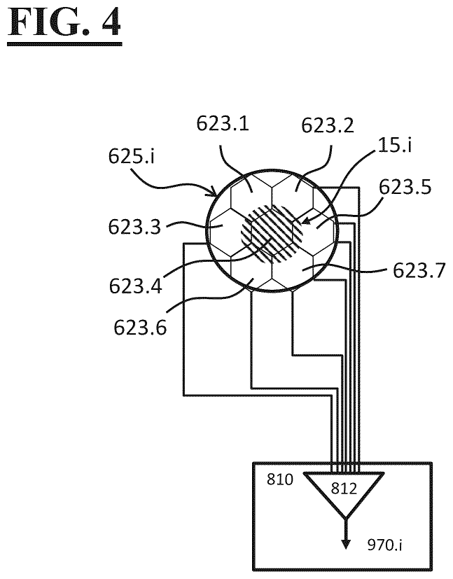

FIG. 4 illustrates an example of a set of detection elements 625.i, comprising 7 individual detection elements 623.1 to 623.7. For example, secondary electron beamlet 15.i is assigned to the set of detection elements 625.i, which comprises the seven detection elements 623.71 to 623.77. Each detection element 623.1 to 623.7 integrates during a certain acquisition time all collected electrons which falls on an area corresponding to the detection element 623.1 to 623.7. Each detection element 623.1 to 623.7 is connected to the image data acquisition unit 810. The signals of the detection elements 623.1 to 623.7 of the set of detection elements 625.i are integrated to form the signal corresponding to a secondary electron beamlet 9.i. For example, the signals of detection elements 623.1 to 623.7 of the set of detection elements 625.i are integrated by the image data acquisition unit 810 to form the intensity signal 970.i corresponding to the secondary electron beamlet 9.i. The integration is performed for example via at least one programmed ASIC 812, in which the assignment of the detection elements 623.1 to 623.7 to the set of the detection elements 625.i is codified. FIG. 4 shows this simplified for a single set of detection elements 625.i only, but it is understood that a similar structure is arranged for all of the sets of detection elements 625 of detector 600. The third raster configuration of secondary beamlets is for example initially adjusted such that a maximum signal strength of each secondary electron beamlet 9 and a minimum crosstalk between adjacent sets of detection elements 625 is achieved. The signal strength of a secondary electron beamlet 9 depends on material contrast and topography of the sample 7 and the overlap of a focus spot with the area of the set of detection elements. An error in an overlap of a focus spot with the area of the set of detection elements thus reduced the signal strength and reduces the signal-to-noise ratio (SNR). It is an aspect of the disclosure to provide a system configured to and a method to monitor the assignment of the third raster configuration to the fourth raster configuration and thus to monitor the signal strength.

Since the detection of the signal intensity typically operates at the high scanning speed of the multi-beam charged particle system 1 of about 20 MHz or more, the data acquisition rate is very high and does not allow a tracking of the focus spots 15 during an image acquisition. Due to the high data acquisition rate of about 20 MHz or more, the integration of the signals of the individual detection elements 623 assigned to a set of detection elements 625 is fixed and cannot easily be adjusted on the fly during an image acquisition. Therefore, if a drift of the third raster configuration arises, the intensity signal recorded by a set of detection elements may drop or cross talk may be generated.

The number J of focus spots 15, the number of detection elements 623 and number of sets of detection elements 625 can be much larger, for example about J=91 or more focus spots 15 can be formed, with a number of sets of detection elements 625 at least as large as the number J of focus spots 15. The number of detection elements for each set of detection elements 625 can be two or can be larger, for example with four or more detection elements 623 per set of detection elements 625. It is however also possible that each set of detection elements 625 comprises only one detection element 623.

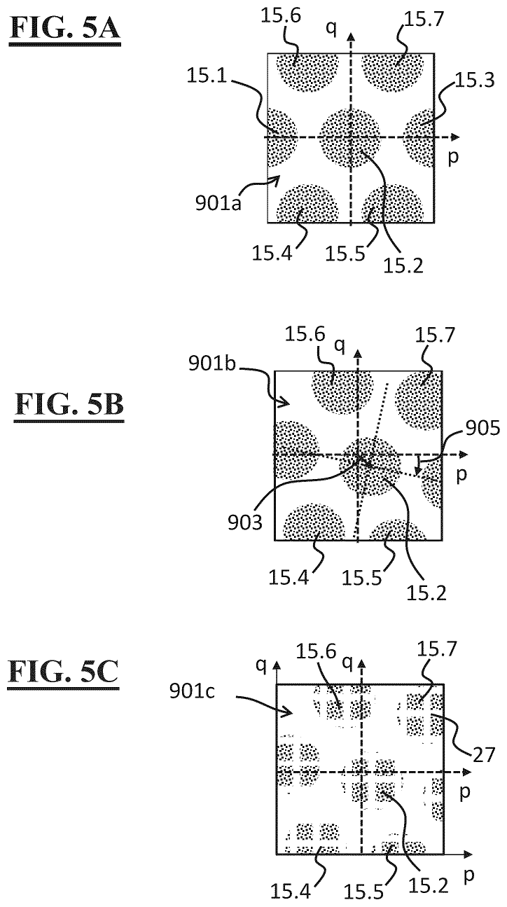

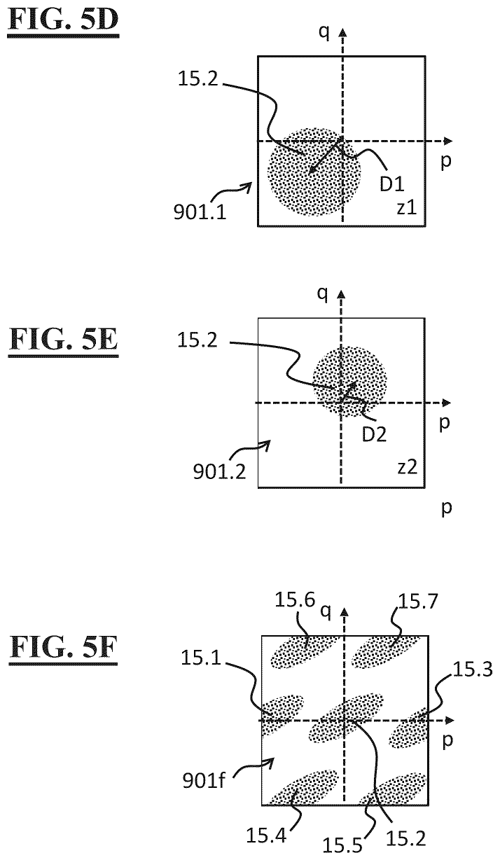

During the monitoring mode of operation, the plurality of focus spots 15 of the secondary beamlets 9 is scanned over the image plane 225 and a plurality of scanning intensity signals 901 is recorded over scan coordinates (p,q). From the stream of intensity signals 970 obtained from a set of detection elements, intensity signals are assigned to corresponding scanning coordinates (p,q) and the scanning intensity signals 901 are generated. Some examples of scanning intensity signals 901 are illustrated in FIGS. 5A-5F. FIG. 5A illustrates a first example of the scanning intensity signal 901a of one secondary beamlet 9.2 scanned over the image plane 225 over scanning coordinates (p,q). In the example of FIG. 5A, the third raster configuration 41.3 of focus spots 15 is aligned with the fourth raster configuration 41.4 of sets of detection elements 625, and the scanning intensity signal 901a is centered, symmetrically and not rotated. This example represents an ideal adjustment with an optimum signal strength. In this example, the scanning range in scanning coordinates (p,q) is selected such that each secondary beamlet 9 is scanned at least partially over the next neighboring sets of detection elements, so for example beamlet 15.1 is also scanned at least partially over set of detection elements 625.2. Therefore, the scanning intensity signal 901a of FIG. 5A comprises further intensity distributions according to the further focus spots 15.1, 15.3, 15.4, 15.5, 15.6 and 15.7 scanned over the set of detection elements 625.2.

FIG. 5B shows an example, where the focus spot 15.2 is decentered by a displacement vector 903 and the third raster is rotated by a rotation angle 905 with respect to the fourth raster. The scanning intensity signal 901b of FIG. 5B thus shows a decentered, asymmetrical, and rotated intensity distribution. The decentering distance 903 of each individual focus spot 15.i of each beamlet 9 is analyzed in each scanning intensity signal 901.i and a magnification change, displacement, anamorphism or rotation is derived. Note that the scanning coordinates (p,q), a scale error or the displacement vector 903 can be determined in arbitrary units, which can be calibrated with respect to for example the known physical dimensions of the sets of detection elements 625. The rotation angle 905 can be determined with respect to an arbitrarily selected coordinate axis.

For illustration, the intensity distribution corresponding to a focus spot 15 in the image plane 225 is illustrated in FIGS. 5A-5F as a single, confined area. However, the focus spots 15 are more of for example a Gaussian shape with an inhomogeneous intensity distribution and a large extension, reaching for example over several sets of detection elements. Thereby, even in perfect alignment, some cross talk might be inevitable. The shape of each focus spots 15 in the scanning intensity signal 901 corresponds to a convolution of a focus spots 15 in image plane 225 with the area of the corresponding set of detection elements 625. This is simplified in FIGS. 5A-5F with an approximately circular area of each set of detection elements 625. The scanning intensity signals 901 corresponding to focus spots 15 in FIGS. 5A-5F merely illustrate the boundary of the focus spots 15 with an intensity threshold of for example 50% of the maximum intensity value applied.

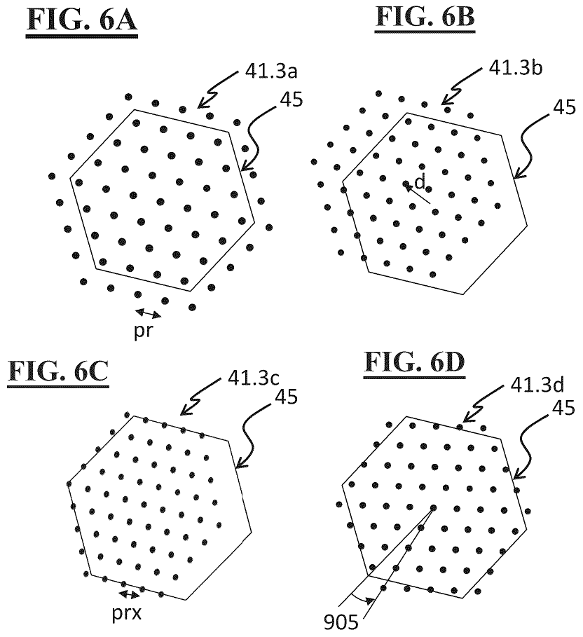

In FIGS. 6A-6B, the scanning intensity signal of the secondary beamlets 9 is achieved for example with a homogeneous reference object, such that the scanning intensity signal 901 is only determined by the overlap of a focus spot 15 of a secondary electron beamlet 9. In an example, during a monitoring operation, the plurality of primary charged particle beamlets is however scanned over the surface 25 of the sample 7, and a scanning intensity signal 901 shows a contrast variation due to a pattern or structure on the surface 25 of an object 7. FIG. 5C illustrates an example, in which a reference object 7R with a regular pattern structure 27 is used. The pattern structure 27 generates a spatial dependence of secondary electron yield and thus an additional contrast variation in the scanning intensity signal 901c. With the pattern structure 27 it is possible to determine the second raster configuration. In the example of FIG. 5C, a regular pattern structure is present on a reference object 7R, and the scanning of the secondary electron beamlets 9 includes a scanning of the focus spots 5 of primary electron beamlets 3 over of the object plane 101, in which the surface 25 of the reference object 7R is arranged. From the regular pattern structure 27 within each secondary electron focus spot 15.1 to 15.7 of the scanning intensity signal 901c, an alignment of the focus spots 5 of the primary charged particle beamlets 3 in the second raster configuration with respect to the regular pattern structure 27 can be determined. The monitoring method thus allows not only the determination of deviations between the third and fourth raster configuration 41.3 and 41.4, but also a deviation of the second raster configuration 41.2 of focus spots 5 of primary beamlets 3 in the object plane 101 from a regular pattern structure 27 of a reference object 7R. A multi-beam system 1 according to the first embodiment can thus be provided with a reference object 7R, and the control unit 800 is configured to arrange the reference object 7R in the object plane 101 before a monitoring method is initiated by the control unit 800.

A multi-beam system 1 according to the first embodiment can further be configured for a determination of a telecentricity property of the plurality of secondary electron beamlets 9. The telecentricity property of the plurality of secondary electron beamlets 9 is defined by the propagation angles of the plurality of secondary electron beamlets 9 at the image plane 225. Ideally, each of the plurality of secondary electron beamlets 9 is impinging perpendicular on the image plane 225, and all beamlets 9 are parallel to each other. Such a plurality of parallel secondary electron beamlets 9 forms a perfect telecentric bundle of beamlets 9. However, due to drifts or other effects, secondary electron beamlets 9 can deviate from perpendicular incidence on the image plane 225. For example, the plurality of secondary electron beamlets 9 can have propagation angles directed to a common point of intersection, forming a homocentric bundle of beamlets 9. In another example, the plurality of secondary electron beamlets 9 are parallel to each other, but with an angle inclined to the surface normal to the image plane 225. The propagation angles of the plurality of secondary electron beamlets 9 together form the telecentricity property of the plurality of secondary electron beamlets 9. To determine the telecentricity property of the plurality of secondary electron beamlets 9, the control unit 800 of the multi beam system 1 can further be configured to repeat an acquisition of a scanning intensity signal 901 after changing a focus plane of the secondary electron imaging system 200. FIG. 5D shows a first scanning intensity signal 901.1 at a first focus plane z1 of the secondary electron imaging system 200, with a first displacement D1 of the focus spot 15.2 in the image plane 225. FIG. 5E shows a second scanning intensity signal 901.2 at a second focus plane z2 of the secondary electron imaging system 200, with a second displacement D2 of the focus spot 15.2 in the image plane 225. From the displacements, a propagation angle a of the secondary electron beamlet corresponding to focus spot 15.2 can be determined according to tan(a)=(D2−D1)/(z2−z1). In this example, a smaller scanning range in scanning coordinates (p,q) is selected.

A multi-beam system 1 according to the first embodiment can further be configured for a determination of a shape of a focus spot 15 of a secondary electron beamlet 9. FIG. 5F illustrates an example, where the focus spot 15 of the plurality of secondary electron beamlets 9 have an elliptical shape. An elliptical shape of the focus spots 15.1 to 15.7 can for example arise from an astigmatism generated within the secondary electron imaging system 200. The effect is exaggerated in FIG. 5F.

During the monitoring operation, the control unit 800 is configured to determine the relative position of each focus points 15 of each secondary beamlet 9 to an assigned set of detection elements 625. In an example, the relative position of a focus spot is determined at the scanning position with the maximum intensity signal. Other examples include an assessment of the scanning intensity signal 901 by image processing and pattern recognition techniques. Such methods may include matching filter techniques or machine learning techniques. Matching filter techniques can benefit from scanning intensity signals corresponding to an ideal adjustment of the multi-beam charged particle system 1. Machine learning techniques can be trained by a plurality of scanning intensity signals with known deviations of raster configurations. Instructions and executables for different numerical methods can be stored in memory 890 and can be performed by control processor 880.

In an example, the multi-beam charged particle imaging system 1 is configured to determine from the plurality of scanning intensity signals 901 the third raster configuration 41.3 of the focus spots 15 of the secondary electron beamlets 9, and to determine a deviation between the third raster configuration 41.3 and the fourth raster configuration 41.4.

The control unit 800 is configured to analyze the deviation and to derive at least one of several deviation components, for example the control processor 880 is configured with instructions to expand the deviation into several different deviation components. Deviation components comprise for example a displacement, a difference in scale, a rotation, or a distortion between the third and fourth raster configuration. However, also other deviation components can be derived. FIGS. 6A-6D show some examples of deviation components of the third raster configuration 41.3 from the fourth raster configuration. The fourth raster configuration is schematically illustrated by frame 45. FIG. 6A illustrates an example of a deviation is imaging scale between the third raster configuration 41.3a with respect to the fourth raster configuration. FIG. 6B shows a lateral displacement of the third raster configuration 41.3b with a displacement vector d. FIG. 6C shows an anamorphic scale error, in which the scale or raster pitch is different in orthogonal directions of the raster configuration 41.3c. FIG. 6D shows a rotation of the third raster configuration 41.3d by an angle 905 with respect to the fourth raster configuration (outlined by frame 45). From the description it is clear that with the term deviation, a relative deviation between the third and the fourth raster configuration is meant. The third and the fourth raster configuration is initially adjusted for example during a calibration of the multi-beam system 1. Any deviation between third and fourth raster configuration due to for example drifts may have different origins. In a first example, the third raster configuration 41.3 of focus spots 15 of secondary electron beamlets 9 might be subject to a drift. In a second example, a drift of the detector 600 might be the origin of a deviation. Such drifts of the detector 600 comprise lateral displacements, thermal expansion, or drifts of an optical relay system of the detector 600 (see FIG. 7 below).

In an example, the control unit 800 of the multi-beam charged particle imaging system 1 is not limited to the determination of the lateral positions of the focus spots 15 of the secondary electron beamlets 9. In an example, the control unit 800 is configured for the determination of the propagation angle of each secondary electron beamlet 9. In this example, the adjustment control unit 840 is configured to jointly scan the focus spots 15 of the secondary electron beamlets 9 perpendicular to the image plane 225 of the secondary electron imaging system 200. A scanning operation perpendicular to the image plane is achieved by controlling at least one of the electro-optical elements 205.1 to 205.5 configured to adjust the focus plane of the secondary electron beamlets 9. Be continuously changing the focus plane, a propagation angle of a secondary beamlet 9 is transferred to a lateral displacement of an intersection position of respective secondary beamlet 9 with the image plane 225 (see FIGS. 5D and 5E). The multi-beam charged particle imaging system 1 according to the first embodiment is configured to determine the lateral positions of the focus spots 15 of the secondary electron beamlets 9 within the image plane 225, and to determine the telecentricity property of the secondary electron beamlets 9. For example, a tilt angle of a telecentric bundle of secondary beamlet2 9, which the plurality of secondary beamlets 9 running in parallel, will result after defocusing in a displacement similar to the displacement shown in FIG. 6B. A deviation from the telecentricity of the plurality of secondary beamlets 9 results after defocusing in a scale error similar to the scale error shown in FIG. 6A. A deviation of an azimuthal angle component of the plurality of secondary electron beamlets 9 results in a rotation of the third raster configuration 41.3, as illustrated in FIG. 6D.

According to a second embodiment of the disclosure, the multi-beam charged particle imaging system 1 is configured to determine a deviation between the third raster configuration 41.3 and the fourth raster configuration 41.4 according to the first embodiment and is further configured to adjust either the third or fourth raster configuration 41.3 or 41.4 to minimize the deviation. Thereby, during an inspection mode of operation, the differences between the third and fourth raster configurations 41.3 and 41.4 are below a predetermined threshold. The adjustment mechanism of the multi-beam charged particle imaging system 1 are configured to adjust the third raster configuration 41.3 or the fourth raster configuration 41.4 or both such that an overlap of a focus point 15 of each secondary beamlet 9 with an assigned set of detection elements 625 is maximized. Thereby, a maximum signal strength of secondary electron signals is achieved, and throughput can be increased, and cross talk is reduced to a minimum.

The multi-beam charged particle imaging system 1 according to the second embodiment therefore comprises an adjustment mechanism for adjusting the third or fourth or both raster configurations 41.3 and 41.4. The adjustment mechanism comprise at least one of the following:
a) elements of the secondary electron optical imaging system 200, such as lenses 205, deflectors such as the second scanning deflector 222, or multi-aperture plate 216.
b) an adjustment or a rotation mechanism of the detector 600, for example the detector 600 can be mounted on a stage connected to actuators, by which the detector 600 can be moved or rotated.
c) an optical mechanism of an optical relay system within the detector 600. For example, a detector 600 can comprise an optical relay system described below in more detail. The optical relay system can comprise a zoom system or an image rotating prism, configured for adjusting the fourth raster configuration to the third raster configuration.
d) the detector 600 with a plurality of detection elements 623 and a control unit 810 can be configured to change the assignment of detection elements 623 to the plurality of sets of detection elements 625.

The multi-beam charged particle imaging system 1 further comprises a control unit 800 with a control processor 880 configured to determine a deviation between the third raster configuration 41.3 of the focus spots 15 of the secondary electron beamlets 9 and the fourth raster configuration 41.4 of the sets of detection elements 625. In an example, the determination is including the determination of a telecentricity property of the secondary electron beamlets 9. The control unit 800 further comprises an adjustment control unit 840, configured to derive at least a control signal from the deviation and to provide the at least one control signal during use to at least one of the adjustment mechanisms. The adjustment mechanism can individually be assigned to deviation components and can be configured for compensating the respective deviation components. The control signals can be derived from pre-determined and stored sensitivity of each adjustment mechanism with respect to the deviation components.

In a first example (a), the secondary electron optical imaging system 200 of the multi-beam charged particle imaging system 1 comprises electron-optical mechanisms 205.1 to 205.5 to adjust a magnification, a deflection, a rotation, or a telecentricity property of the plurality of secondary electron beamlets 9. For example, the secondary electron optical imaging system 200 can comprise at least two electron-optical imaging lenses 205.1 to 205.5 of variable optical power to adjust a magnification of the plurality of secondary electron beamlets 9. For example, the secondary electron optical imaging system 200 can comprise at least one magnetic lens 205.4 and 205.5 of variable optical power to adjust a rotation of the plurality of secondary electron beamlets. For example, the secondary electron optical imaging system 200 can comprise at least one deflector 222, configured for an additional, quasi-static displacement of the plurality of secondary electron beamlets 9. For example, the second scanning deflector 222 can be provided by the control unit 800 with a constant offset voltage to cause an offset displacement of the plurality of secondary electron beamlets 9. In a further example, the elements of the secondary electron optical imaging system 200 comprise a mechanism to adjust a telecentricity property of the secondary electron beamlets 9.

In a second example (b), the detector 600 comprises a mechanical mechanism. The control unit 800 can be configured to jointly adjust a displacement or a rotation of the sets of detections elements 625. For example, the detector 600 can be mounted on an actuated stage configured for a lateral adjustment and rotation of the position of the detector 600.

In a third example (c), the detector 600 comprises an optical mechanism to adjust a magnification or a displacement or a rotation. An example of a detector of the third example is illustrated in FIG. 7. The detector 600 comprises an electron-to-light conversion element 602, arranged in the image plane 225. The electron-to-light conversion element 602 is configured to convert the secondary electrons in the focus spots 15.1 to 15.3 of the secondary electron beamlets 9 into light. The detector further comprises an optical relay system with optical elements 605 and 611 for imaging and guiding the excited light from the electron-to-light conversion element 602 to detection elements 623. For that purpose, the optical relay system can comprise a zoom lens system 611, mirrors 607, rotating prisms (not shown) and light guiding fibers 615. In the example of FIG. 7, the detector 600 is configured to image the excited light from the electron-to-light conversion element 602 into an image plane 613, in which a plurality of entrance openings 613 of optical fibers 615 are arranged. The fourth raster configuration 41.4 is thereby defined by the arrangement of the entrance openings 613 of the optical fibers 615, and by the magnification by the optical system comprising lens 605 and zoom lens 611. The adjustment mechanism of the multi-beam system 1 of this example comprise the optical zoom 611. Furthermore, the plurality of fiber ends 613 are fixed in a movable frame 617, which can be displaced or rotated. Thereby, a position and a rotation of the fourth raster configuration of entrance openings 613 of fibers 615, corresponding to the sets of detection elements 625, can be adjusted to the third raster configuration of focus points 15 formed in the image plane 225.

The detector 600 further comprises a monitoring system 230 with a high-resolution detector 232 and an optical relay lens 235 of the monitoring system. The monitoring system 230 can optionally be retractable (indicated by arrow 630) and/or can be coupled by a beam divider 237. The high-resolution detector 232 typically operates at a slow frame rate of for example about 10 to 20 frames per second and is thus not capable to collect the intensity signals at scanning speed of about 20 MHz. The high-resolution detector 232 is however able to detect the raster configuration. As will be explained below, the fifth embodiment of the disclosure provides a reliable and fast method of calibrating of the monitoring system 230.

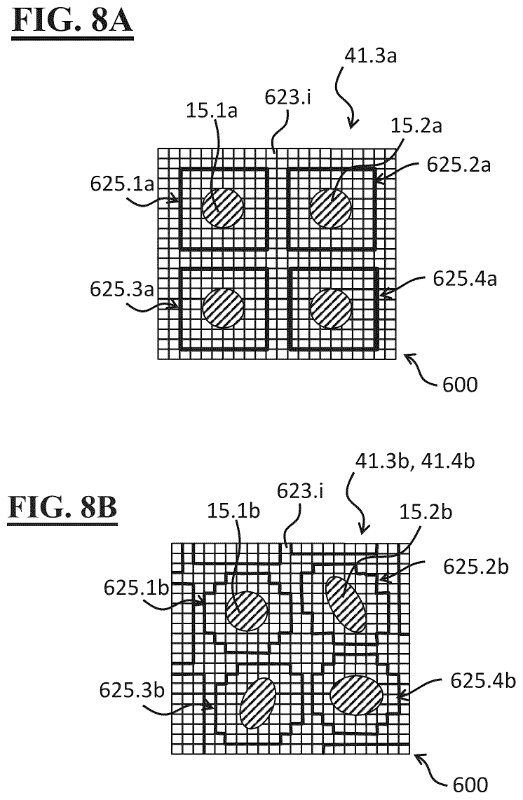

In a fourth example, the detector 600 comprises a plurality of detection elements 623 and a control mechanism to modify the assignment of the plurality of detection elements 623 to the sets of detections elements 625. Thereby, a modified fourth raster configuration 41.4b, formed by modified sets of detections elements 625b, is adjusted to a third raster configuration 41.3b of the focus spots 15b of the secondary electron beamlets 9. An example is illustrated in FIGS. 8A-8B. FIG. 8A shows a first raster configuration 41.3a of focus spots 15.1a to 15.4a. For example, the secondary electrons of the focus spot 15.1a are accumulated by the set of detection elements 625.1a, and the secondary electrons of the focus spot 15.2a are accumulated by the set of detection elements 625.2a. The first assignment of detection elements 623 to sets of detection elements 625.1a to 625.4a is initially determined and stored in a memory. FIG. 8B shows a modified raster configuration 41.3b of focus spots 15.1b to 15.4b according to a drift of for example the secondary electron imaging system 200. From each focus spot 15b, a modified set of detection elements 625.1b to 625.4b is determined and the modified assignment is used in a downstream inspection task. The modified set of detection elements 625b can not only be at different lateral position corresponding to the focus spots 15b but can also be of different shape or number of detection elements. Thereby, a shape deviation of a focus spot 15 can be considered as well. Thereby, a maximum signal strength with a minimum cross talk is achieved. The multi-beam system 1 according to the first embodiment can be configured to detect a deviation in shape of a focus spot 15 from the scanning intensity signals 901 and can be configured to consider the spot deviation during the adjustment by the adjustment mechanism according to the second embodiment.

With at least one of the adjustment mechanisms or any combination thereof, for example a deviation in magnification or scale, an anamorphism, a displacement, or a rotation between the third raster configuration 41.3 and/or the fourth raster configuration 41.4 is adjusted. In an example, the control unit 800 is configured to frequently switch during operation from an inspection mode of operation to the monitoring mode of operation and to frequently determine a deviation between the third raster configuration 41.3 and the fourth raster configuration 41.4. The multi-beam charged particle imaging system 1 is further configured to frequently adjust the adjustment mechanism to minimize the deviation between the third and fourth raster configuration. Thereby, maximum signal strength, minimal noise and highest imaging precision is continuously maintained during an inspection mode of operation. The control unit 800 of the multi-beam charged particle imaging system 1 can for example be configured to switch to a monitoring mode of operation between two inspection sites of a wafer 7, or between the exchange of a first wafer with a second wafer.

The system according to the second embodiment is however not limited to the adjustment of the third raster configuration 41.3 or the fourth raster configuration 41.4. With the system configured for determining the second raster configuration 41.2 of the focus spots 5 of the plurality of primary charged particle beamlets 3 with respect to a regular pattern structure 27 of a reference object 7R, it is also possible to adjust the second raster configuration 41.2 of the focus spots 5 of the plurality of primary charged particle beamlets 3 with an adjustment mechanism of the primary beam illumination system 100.

The adjustment mechanism of the primary beam illumination system 100 are for example lens elements 307, 308, 103 and 102, by which a magnification and image rotation can be adjusted, or a deflector, including the scanning deflector 110, by which a lateral position of the second raster configuration 41.2 can be adjusted.

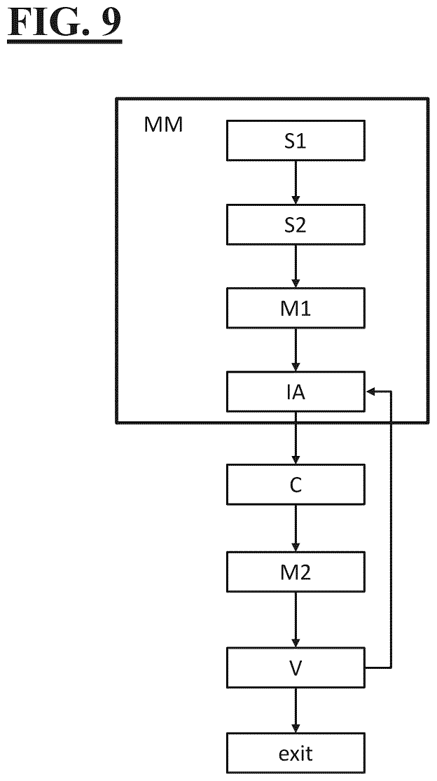

According to a third embodiment of the disclosure, a monitoring method MM is provided to determine a deviation between a third raster configuration of focus spots of a plurality of secondary electron beamlets and a fourth raster configuration of a plurality of sets of detection elements. The method MM is illustrated in FIG. 9.

The monitoring method comprises a first triggering step S1, during which a monitoring is triggered, for example during an inspection operation. The monitoring method further comprises optionally a step S2, during which a reference object 7R is placed in the object plane 101 of the multi-beam charged particle system 1. A reference object 7R can for example be placed in the circumference of a wafer mount of the sample stage 500. A reference object can for example comprise an unstructured surface, or a regular microscopic pattern 27.

In step M1, the focus spots 15 of the secondary electron beamlets 9 are jointly scanned over the image plane 225, in which a detector 600 is arranged. A scanning intensity signal 901 over scanning coordinates (p,q) is recorded for each secondary electron beamlet 9. The scanning intensity signal 901 corresponds to the signal collected by a set of detection elements, which is assigned to a secondary electron beamlet. Some examples of scanning intensity signal 901 are illustrated in FIGS. 5A-5F, described above.

An example of step M1 comprises a scanning deflection of the plurality of primary charged particle beamlets 3 with a first deflection scanner 110 over a surface of a sample 7. During operation, a plurality of moving irradiation positions in a raster configuration is formed on the surface of the sample 7. The moving irradiation positions are forming a plurality of origins of the secondary beamlets 9. In an example, step M1 comprises a scanning deflection of the plurality of secondary charged particle beamlets 9 with a second scanning deflector 222. During the monitoring mode of operation according to the third embodiment, the scanning deflection of the plurality of first or secondary charged particle beamlets is controlled to cause a scanning movement of the focus spots 15 of the secondary electron beamlets 9 in the image plane 225 of the secondary electron imaging system 200. The scanning movement comprises a lateral scanning as well as a scanning or changing of the focus plane. Step M1 therefore comprises a control of at least one of the first and second deflection scanners 110, 222 such that the focus points 15 of the secondary electron beamlets 9 are scanned in the image plane 115 of the secondary electron imaging system 200. In an example, the first deflection scanner 110 is set in an off mode of operation, and the secondary electron beamlets 9 are scanning deflected by the second deflection scanner 222. In an example, the second deflection scanner 222 is set in an off mode of operation, and the scanning movement of the origins of the secondary electron beamlets 9 is not compensated. In an example, both first and second deflection scanners 110 and 222 are controlled in an unsynchronized operation, such that a residual scanning movement of the focus points 15 of the secondary electron beamlets 9 in the image plane 225 is achieved. In an example, a scanning of the focus plane of the plurality of secondary electron beamlets 9 is achieved by changing the power of at least one of the electron-optical lens elements 205 of the secondary electron imaging system 200.

In step IA, the relative position of each secondary beamlet 9 to the set of detection elements 625 is determined from each scanning intensity signal 901 achieved in step M1. Some examples are illustrated in FIG. 5A-5F described above. The relative position can for example be determined according to the scanning position of the maximum intensity signal. Thereby, a deviation between the third raster configuration 41.3 of the focus spots 15 of the secondary electron beamlets 9 and the fourth raster configuration 41.4 of the sets of detection elements 625 is determined.

The relative position of a focus spot 15 is determined from an assessment of the scanning intensity signal 901. The assessment can utilize image processing and pattern recognition techniques, or machine learning techniques. Image processing can be performed by matching filter techniques or image correlation techniques. Matching filter techniques can benefit from scanning intensity signals 901 corresponding to an ideal adjustment of the multi-beam charged particle system 1. Machine learning executables can be trained by a plurality of scanning intensity signals 901 with known deviations of raster configurations.

According to the third embodiment, step M1 is configured such that each focus point 15 of the secondary beamlets 9 is scanned over an assigned set of detection elements 625, and a plurality of streams of image data is recorded and assigned to corresponding scanning coordinates of the focus points 15. An overlap signal of a focus point with a set of detection elements 625 is determined in step IA, and a maximum signal strength is determined from an optimal overlapping position of each focus point with the assigned set of detection elements 625. The scanning range of the secondary beamlets 9 can be adjusted to scan over at least one set of detection elements 625, for example three sets of detection elements 625. Thereby, as illustrated in FIG. 5B, also a rotation between the third and fourth raster configuration can be determined with high precision even from a single scanning intensity signal 901.

During step IA, displacements of a plurality of individual focus spots 15.i within a plurality of scanning intensity signal 901.i are determined. From the plurality of displacements, the deviation of the third raster configuration 41.3 with respect to the fourth raster configuration 41.4 is determined. Some examples of deviations are illustrated in FIGS. 6A-6D, described above.

In a further example of a monitoring method according the third embodiment, the acquisition of scanning intensity signal 901 is repeated at least two times for at least two different focusing powers of the secondary electron imaging system 200. Thereby, a focus plane is changed, in which the focus spots 15 of the plurality of secondary electron beamlets 9 are formed, and at least one focus plane deviates from the image plane 225. During step IA, a telecentricity property of the plurality of secondary electron beamlets 9 is determined from the at least two scanning intensity signal 901.1 and 901.2 (see FIGS. 5D and 5E). A first displacement D1 of a focus spot 15.2 in the first scanning intensity signal 901.1 and a second displacement D1 of the focus spot 15.2 in the second scanning intensity signal 901.2 is determined as described above. From the difference between the first and second displacement, a propagation angle a of the corresponding secondary electron beamlet is determined according to tan(a)=(D2−D1)/(z2−z1).

In a further example, during a monitoring method according the third embodiment, the plurality of primary charged particle beamlets 3 is scanned over the surface 25 of the sample 7, and the scanning intensity signal 901 shows a contrast variation due to a pattern or structure 27 on the surface 25 of an object 7. In an example, a reference object 7R with for example a regular pattern structure 27 is used during the acquisition of the scanning intensity signals 901, as illustrated in FIG. 5C. The pattern structure 27 generates a spatial dependence of secondary electron yield and thus an additional contrast variation in the scanning intensity signal 901. In an example of the monitoring method according the third embodiment, step IA further comprises an assessment of the pattern structure 27 within each focus spot 15 within the scanning intensity signals 901. The assessment can include image processing and machine learning methods, the latter being trained by a plurality of labelled scanning intensity signal 901 images. With this method it is possible to determine the second raster configuration 41.2 of focus spots 5 of the plurality of primary beamlets 3. The monitoring method according to the third embodiment thus allows not only the determination of deviations between the third and fourth raster configuration 41.3 and 41.4, but also a deviation of the second raster configuration 41.2 of focus spots 5 of primary beamlets 3 in the object plane 101 from a regular pattern structure 27 of a reference object 7R.

In a further example of a monitoring operation according the third embodiment, the acquisition of scanning intensity signal 901 is repeated at least two times for at least two different focusing powers of the primary beam illumination system 100. With a change of the focusing power of the primary beam illumination system 100, the size of the primary focus spots 5 in the object plane 101 changes and therefore also the size of the origins or sources of the secondary electrons (compare the different sizes in FIGS. 5D and 5E). Therefore, also the size of the focus spots 15 of the secondary electron beamlets 9 in the image plane 225 changes. From the change of size, an ideal focusing power of the primary beam illumination system 100 can be determined at the position of minimum size of focus spots 15 or maximum signal strength of the intensity collected of a secondary electron beamlet 9.

In a further example of a monitoring method according the third embodiment, the analysis of the scanning intensity signal 901 during step IA can comprise a determination of a deviation of the shape of focus points 15. An example is illustrated in FIG. 5F with astigmatic beamlets 9, leading to an elliptical shape of the focus spots 15. In such a scenario, typically a signal strength is reduced, and cross talk is increased.

According to the fourth embodiment of the disclosure, the deviation determined according to the third embodiment is utilized to control a set of adjustment mechanism. The method according to the fourth embodiment comprises the steps of the third embodiment. The set of adjustment mechanisms of the multi-beam charged particle imaging system 1 are configured to adjust the third raster configuration or the fourth raster configuration or both such that an overlap of each secondary beamlet with a set of detection elements is maximized. Thereby, an optimum signal strength of secondary electrons is achieved, and a cross talk is reduced to a minimum.

According to the fourth embodiment, the method of FIG. 9 further comprises step C. During step C, the deviation between the third and the fourth raster configuration is analyzed, and at least one of several deviation components is determined. The determination of the systematic deviation components between third raster configuration 41.3 and fourth raster configuration 41.4 can for example be performed by approximating of a vector transformation to the plurality of displacement vectors at the raster positions of the third raster configuration 41.3. For example, a rotation between the raster configurations is typically centered at a central focus spot with increasing displacement with increasing distance to the rotation center. Deviation components comprise for example a displacement, a difference in scale, an anamorphism, a rotation, or a distortion between the third and fourth raster configuration. Deviation components can further comprise a telecentricity aberration, or a deviation of the second raster configuration 41.2 of the focus points 5 of the primary charge particle beamlets 3 in the object plane 101.

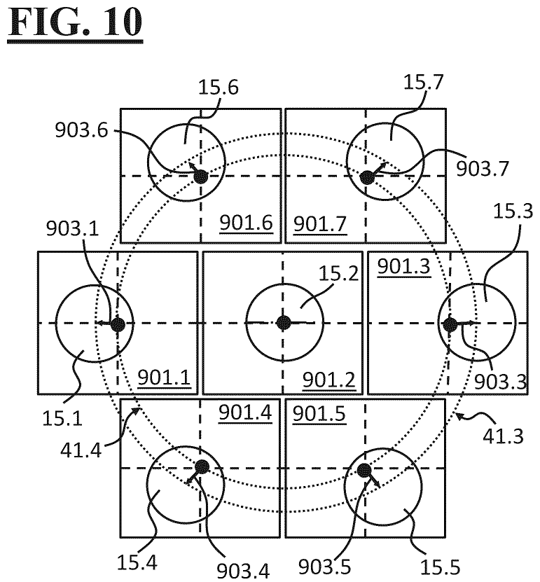

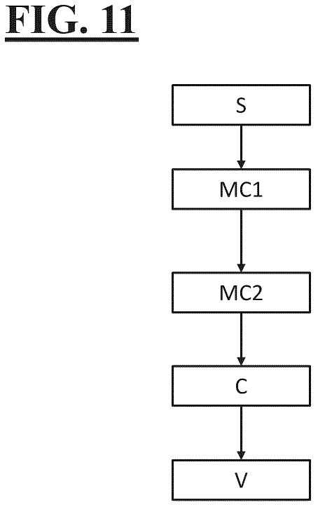

An example is illustrated in FIG. 10. FIG. 10 shows seven scanning intensity signals 901.1 to 901.7, each centered at raster grid positions of the fourth raster configuration 41.4. The raster grid positions are highlighted by bold dots in FIG. 10 and comprise a central raster grid position and six raster grid positions arranged on a circle with a radius corresponding to the fourth raster configuration 41.4. Each of the seven scanning intensity signals 901.1 to 901.7 is obtained by scanning of the secondary electron beamlets 9 over the assigned set of detection elements 625. Note that each focus spot 15.1 to 15.7 illustrated in FIG. 10 is merely the convolution of a focus spot 15 of a secondary electron beamlet 9 with a set of detection elements 625 and is therefore not identical to the focus spot 15 formed in the image plane 225. The intensity signals within the scanning intensity signals 901.1 to 901.7 are merely corresponding to the focus points 15.1 to 15.7. However, a center position of a focus spot 15 can nevertheless be determined with high precision. Each of the scanning intensity signals 901.1 to 901.7 is analyzed and a center of each focus spots 15.1 to 15.7 is determined. The displacements 903.1 to 903.7 of the centers of each focus spots 15.1 to 15.7 are analyzed together to derive a deviation component. In FIG. 10, the example of a deviation in magnification or scale is illustrated. All displacement vectors 903.1 to 903.7, except for the central spot 15.2, show a component in radial direction with endpoints on a circle representing the third raster configuration 41.3 with the scale or magnification deviation.

The deviation components can individually be assigned to an adjustment mechanism. The assignment can be stored in a memory of the multi-beam system 1. From the deviation components, a plurality of control signals is determined and provided to the adjustment mechanism. The control signals can be derived from pre-determined and stored sensitivities of each adjustment mechanism with respect to the deviation components.

The result of the adjustment of the third to the fourth raster configuration is determined in a repeated monitoring step M2, which can be identical to step ML. In a final step V, the signal strengths of each of the secondary electron beamlets 9 collected by the assigned sets of detection elements 625 are controlled and the adjustment achieved in step C is either verified or the method is iterated, beginning with step IA. After a successful achievement of a maximum signal strength of each of the secondary electron beamlets 9, the monitoring and adjustment method is completed with step “exit” and an inspection operation can be continued.

The monitoring method and the adjustment methods are not limited to the determination of the lateral positions of the focus spots of the secondary electron beamlets. In an example, the monitoring method is configured for the determination of the propagation angle of each secondary electron beamlet. In this example, the monitoring method comprises during step M1 a jointly scanning of the focus spots 15 of the secondary electron beamlets 9 perpendicular to the image plane 225 of the secondary electron imaging system 200. The scanning perpendicular to the image plane 225 is achieved by changing the focus plane of the secondary electron beamlets 9 by at least an electro-optical element 205.1 to 205.5 of the secondary electron imaging system 200. By continuously scanning the focus plane through the image plane 225, a propagation angle of a secondary beamlet 9 is transferred to a lateral displacement of an intersection position of that secondary beamlet 9 in the image plane 225. The monitoring operation according to the third embodiment can therefore comprise the steps of determining the lateral positions of the focus spots 15 of the secondary electron beamlets 9 within the image plane 225, and the steps of determining the telecentricity property of the secondary electron beamlets 9.

The deviation can also comprise deviation components of a deviation from a perfect telecentricity of the plurality of secondary electron beamlets 9. The adjustment mechanism according to the adjustment method can comprise the adjustment of a telecentricity property of the secondary beamlets 9. The telecentricity property of the secondary beamlets 9 can be adjusted to achieve a perfect telecentricity of secondary beamlets 9. Thereby, an optimum signal strength of secondary electrons 9 is achieved even if the focus spots 15 of the secondary electron beamlets 9 are not perfectly formed in the image plane 225, for example due to a topography of a sample 7 or charging effects of the sample 7.

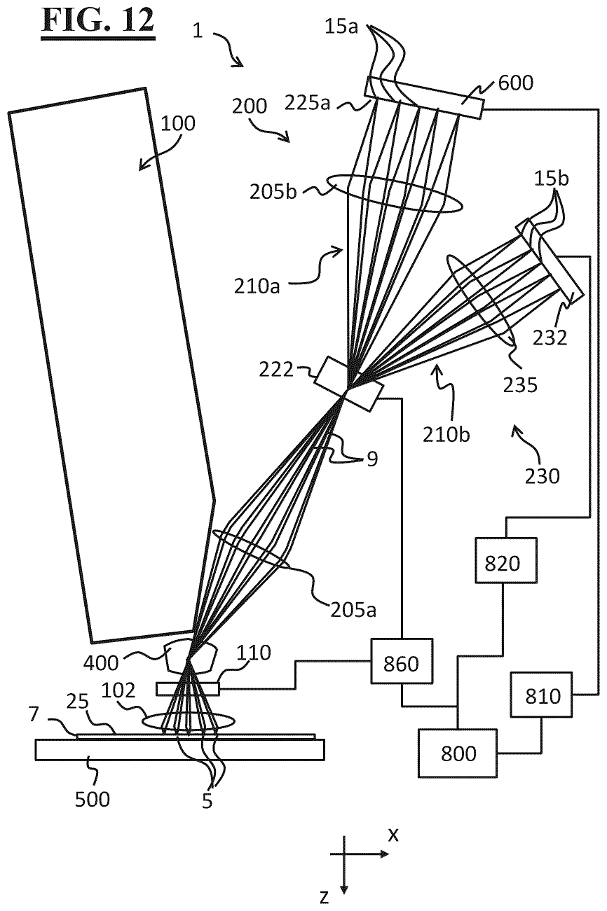

According to the fifth embodiment of the disclosure, a method of calibrating a second monitoring system is provided. A multi-beam charged particle system 1 comprises a second monitoring system 230. In an example, the second monitoring system 230 is given by an optionally retractable monitoring system 230, configured to image the focus spots of the secondary electron beamlets on a high-resolution detector. Such a system is shown in FIG. 1. In a further example, the second monitoring system 230 is given by an optionally retractable optical monitoring system 230 in the optical relay system of a detector 600, as illustrated in FIG. 7. Various other second monitoring system are possible, for example a beam deflector in the secondary electron beam path, configured to alternatively guide the plurality of secondary electron beamlets on a second detector 232. Such a system is illustrated in FIG. 12. FIG. 12 illustrates a multi-beam system 1 according to the first and second embodiment; reference is made to FIG. 1 and the description of FIG. 1. The secondary electron imaging system 200 comprises a scanning beam deflector 222, which is configured to deflect the plurality of secondary electron beamlets 9 either in a first direction, following a first secondary electron imaging path 201a, or in a second direction, following a second secondary electron imaging path 201b. In the image plane 225a in the first secondary electron imaging path 201a, the detector 600 is arranged. The second secondary electron imaging path 201b forms the second monitoring system 230 with a high-resolution detector 232. With any second monitoring system 230, the fifth raster configuration of focus spots 15b of the secondary electron beamlets 9 can be monitored with the high-resolution detector 232. However, the second monitoring system 230 involves a calibration of the measurement of the fifth raster configuration with respect to the third raster configuration, which is formed in the image plane 225.

According to the fifth embodiment, a method of calibrating a second monitoring system 230 is provided. The second monitoring system 230 is including a second, high-resolution detector 232. With the apparatus and methods according to the first to fourth embodiments, the third raster configuration 41.3 and a telecentricity property of the focus spots 15 of the plurality of secondary electron beamlets 9 can be determined with the main detector 600, arranged in the image plane 225. The third raster configuration and telecentricity property can be adjusted by adjustments mechanism, and the second monitoring system 230 can be calibrated with the determined or adjusted raster configuration and telecentricity property. Thereby, a precise calibration of the second monitoring system 230 is possible. The calibration of the second monitoring system 230 according to the fifth embodiment can frequently or automatically be repeated without supervised interaction. Thereby, during an inspection operation, a monitoring with high precision can be maintained and the signal strength and performance of an inspection operation can be maintained at an optimized level.

FIG. 11 illustrates the steps of the calibration method according to the fifth embodiment. In a first step S, a calibration is triggered, and a metrology object is positioned in the object plane 101 of the multi-beam charged particle system 1.

In step MC1, the fifth raster configuration of the focus spots 15 of the secondary electron beamlets 9 is determined with the second monitoring system 230. The fifth raster configuration is determined in a second coordinate system and with a second scale and a second rotation angle of the second monitoring system 230.

In step MC2, the third raster configuration 41.3 of the focus spots 15b of the secondary electron beamlets 9 in the image plane 225 is determined with the method provided in the third embodiment of the disclosure. Step MC2 therefore comprises step M1, during which the focus spots 15 of the secondary electron beamlets 9 are jointly scanned over the image plane 225, in which a detector 600 is arranged. Step MC2 further comprises step IA, during which the relative position of each secondary beamlet 9 to the set of detection elements 625 is determined from the scanning intensity signals 901 achieved in step M1. The third raster configuration is determined in a first coordinate system and with a first scale and first rotation angle of the detector 600.

In step C, the second coordinate system and with a second scale and a second rotation angle of the second monitoring system 230 is adjusted to the first coordinate system and with a first scale and first rotation angle of the detector 600. The adjustment is performed virtually, for example by numerical adjustment of the second coordinate system to the first coordinate system. The adjustment can further comprise a mechanical or optical adjustment of the position and scale of the coordinate systems, for example by a mechanical adjustment of the optionally retractable second monitoring system, or by a calibration of the deflector 222. After calibrating in step C, the measurement results provided by the second monitoring system 230 directly correspond to a determination result of the monitoring method according to the third embodiment.

The order of steps MC1 and MC2 can be also reversed. The calibration method can further comprise a verification step V, in which step MC1 or step MC2 or both steps are repeated, and the calibration is verified.

The method according the third embodiment, performed during step MC2, therefore enables a precise calibration of a second monitoring system 230 of a multi-beam charged particle system 1. The calibration according to the fifth embodiment can thus be utilized in a multi-beam charged particle system 1 during use, without any further special metrology mechanism or without user interaction. Therefore, a drift for example in the second monitoring system can be compensated and the second monitoring system can be re-calibrated.

In a further embodiment, a method of the disclosure is applied to a calibration of a synchronized operation of the first deflection scanner 110 and the second deflection scanner 222. For example, during a method according to the third embodiment, a plurality of scanning intensity signal 901 is generated and an offset of the first or second deflection scanner (110, 222) is determined. An offset of a deflection scanner introduces a displacement of a raster configuration, similar to the displacement illustrated in FIG. 6B. With a method according to the fourth embodiment, a deflector offset of either the first or second deflection scanner (110, 222) is adjusted.

In the context of the disclosure, a raster configuration is an arrangement of elements (here: focus positions of primary or secondary beamlets) in a regular raster grid, for example a hexagonal raster grid, at predefined relative distances between the plurality of elements. The absolute size or scale and the rotation of the raster configuration can however be different at different positions within the multi-beam charged particle imaging system. Typical raster configurations comprise for example more than 60, more than 90 or even more than 900 primary beamlets, arranged in a hexagonal or rectangular raster. Other raster configurations are circular raster configurations, in which a plurality of beamlets is arranged on at least one circular ring.

The disclosure is not restricted to the specific embodiments and examples, but variations of the embodiments are also possible. Although in principle reference is made to a wafer as an object, the disclosure is also applicable to other objects as used in semiconductor manufacturing. By way of example, the object can also be a mask, for example a mask for EUV lithography, rather than a semiconductor wafer. In contrast to semiconductor wafers, such masks are generally rectangular and have a significantly greater thickness.

The disclosure is further described based on a multi-beam system having a plurality of primary electron beamlets, but other charged particles, for example helium ions, may also be used.

The disclosure is further described by following clauses:

Clause 1: Method of operating a multi-beam charged particle imaging system (1), comprising:
generating a plurality of primary charged particle beamlets (3) in a first raster configuration (41.1),
generating, by irradiation of a surface (25) of an object (7) with the plurality of primary charged particle beamlets (3), a plurality of secondary charged particle beamlets (9),
forming secondary electron focus spots (15) of the plurality of secondary charged particle beamlets (9) in a third raster configuration (41.3) on a detector (600),
scanning of the secondary electron focus spots (15) over the detector (600),
recording a plurality of scanning intensity signals (901),
determining, from the plurality of scanning intensity signals (901), the third raster configuration 41.3.

Clause 2: The method according to clause (1), wherein the determining of the third raster configuration (41.3) comprises at least one of an image processing, a matched filtering, or a machine learning method applied to the plurality of scanning intensity signals (901), and determining of a scale, a lateral position, or a rotation of the third raster configuration (41.3).

Clause 3: The method according to clauses 1 or 2, wherein the detector (600) comprises a plurality of sets of detection elements (625) being arranged in a fourth raster configuration (41.4), and wherein the third raster configuration (41.3) is determined from laterally scanning of the secondary electron focus spots (15) over the plurality of sets of detection elements (625).

Clause 4: The method according to clause 3, wherein the determining of the third raster configuration (41.3) comprises determining of a deviation between the third raster configuration (41.3) and the fourth raster configuration (41.4).

Clause 5: The method according to any of the clauses 1 to 4, wherein the determining the third raster configuration (41.3) from the scanning intensity signals (901) comprises at least one of an image processing, a matched filtering, or a machine learning method applied to the scanning intensity signals (901).

Clause 6: The method according to any of the clauses 1 to 5, further comprising the step of determination of a telecentricity property of the secondary electron beamlets (9), wherein telecentricity property is determined from longitudinally scanning or defocusing of the secondary electron focus spots (15) perpendicular to an image plane (225), in which the detector (600) is arranged.

Clause 7: The method according to any of the clauses 1 to 6, wherein the detector (600) further comprises a conversion of secondary electrons to light with an electron-to-light conversion element (602) arranged in an image plane (225), and wherein the secondary electron focus spots (15) are formed on the electron-to-light conversion element (602).

Clause 8: The method according to any of the clauses 1 to 6, wherein each of the plurality of sets of detection elements (625) comprises at least two detection elements (623), and wherein the step of recording the plurality of scanning intensity signals (901) comprises an integration of the scanning signals of the at least two detection element (623) of a set of detection elements (625).

Clause 9: The method according to any of the clauses 1 to 8, wherein the step of scanning of the secondary electron focus spots (15) comprises a scanning of the plurality of primary charged particle beamlets (3) over the object (7) by a first deflection scanner (110).

Clause 10: The method according to any of the clauses 1 to 8, wherein the step of scanning of the secondary electron focus spots (15) comprises a scanning of the plurality of secondary charged particle beamlets (9) by a second deflection scanner (222).

Clause 11: The method according to any of the clauses 1 to 8, wherein the step of scanning of the secondary electron focus spots (15) comprises a scanning of the plurality of primary charged particle beamlets (3) over the object (7) by a first deflection scanner (110) and a scanning of the plurality of secondary charged particle beamlets (9) by a second deflection scanner (222).

Clause 12: The method according to any of the clauses 1 to 11, further comprising the step of modifying the third raster configuration (41.3) of the secondary electron focus spots (15).

Clause 13: The method according to clause 12, further comprising at least one of an adjustment of an imaging scale, an adjustment of an anamorphism, an adjustment of a displacement, or an adjustment of a rotation of the third raster configuration (41.3).

Clause 14: The method according to clauses 12 or 13, wherein the detector (600) comprises an electron to light conversion element (602), the method comprises
exciting a plurality of light beams at the secondary electron focus spots (15) of the plurality of secondary charged particle beamlets (9) formed on the electron to light conversion element (602), and
imaging the excited light beams from the electron to light conversion element (602) on the detection elements (623) by an optical relay system (605, 611, 615), and
   wherein the step of modifying comprises an adjustment of a magnification, a displacement or a rotation of the plurality of light beams by the optical relay system (605, 611, 615).

Clause 15: The method according to clause 14, wherein the detector (600) further comprises an optical zoom system (611) and wherein the adjustment comprises an adjustment of a magnification of the optical zoom system (611).

Clause 16: Method according to any of the clauses 12 to 15, wherein the detector (600) comprises a plurality of sets of detection elements (625) arranged in a fourth raster configuration (41.4), the method further comprising:
adjusting the fourth raster configuration (41.4) of the plurality of sets of detection elements (625).

Clause 17: The method according to clause 16, wherein the adjusting of the fourth raster configuration (41.4) comprises at least one of a re-assignment of at least one detection element (623) to modify the plurality of sets of detection elements (625).

Clause 18: The method according to clauses 16 or 17, further comprising adjusting the fourth raster configuration (41.4) by a mechanical mechanism for displacing or rotating the detection elements (623) of the detector (600).

Clause 19: Method of operation of a multi-beam charged particle imaging system (1), comprising:
generating a plurality of primary charged particle beamlets (3) in a first raster configuration (41.1),
generating, by irradiation of a surface (25) of an object (7) with the plurality of primary charged particle beamlets (3), a plurality of secondary charged particle beamlets (9) in a second raster configuration (41.2),
forming secondary electron focus spots (15) of the plurality of secondary charged particle beamlets (9) on a detector (600) in a third raster configuration (41.3),
controlling an operation mode of the multi-beam charged particle imaging system (1) for operating the multi-beam charged particle imaging system (1) in either a first or inspection mode for obtaining an image of a surface segment of the object (7) or in a second or monitoring mode for determining of the third raster configuration (41.3).

Clause 20: The method according to clause 19, wherein, during the operating the multi-beam charged particle imaging system (1) in the first mode, the method comprises the step of operating of a first deflection scanner (110) for deflecting the plurality of primary charged particle beamlets (3) and of a second deflection scanner (222) for deflecting the plurality of secondary charged particle beamlets (9) in a synchronized manner to keep the secondary electron focus spots (15) of the plurality of secondary charged particle beamlets (9) at constant positions on the detector (900).

Clause 21: The method according to clause 19 or 20, wherein, during the operating the multi-beam charged particle imaging system (1) in the second mode, the method comprises the step of operating of either the first deflection scanner (110) for deflecting the plurality of primary charged particle beamlets (3) or of the second deflection scanner (222) for deflecting the plurality of secondary charged particle beamlets (9), or of both first and second deflection scanner (110, 222) in a manner to scan the secondary electron focus spots (15) of the plurality of secondary charged particle beamlets (9) over the detector (600).

Clause 22: The method according to clause 21, further comprising, during the operating the multi-beam charged particle imaging system (1) in the second mode, any of the method steps of clauses 1 to 18.

Clause 23: A multi-beam charged particle imaging system (1), comprising
a multi-beam generator (300) for generating during use a plurality of primary charged particle beamlets (3) in a first raster configuration (41.1),
a primary electron optical system (100) configured for forming during use a plurality of focus spots (5) of the plurality of primary charged particle beamlets (3) on a surface (25) of an object (7), wherein the primary electron optical system (100) comprises a first deflection scanner (110),
a beam divider (400),
a detector (600), comprising a plurality of sets of detection elements (625) in a fourth raster configuration (41.4),
a secondary electron optical system (200) for forming a plurality of focus spots (15) of secondary electron beamlets (9) in a third raster configuration (41.3) on the detector (600), whereby the plurality of secondary charged particle beamlets (9) are originating from the focus spots (5) of the plurality of primary charged particle beamlets (3), and wherein the secondary electron optical system (200) comprises a second deflection scanner (222),
a control unit (800), configured for switching an operation of the first and second deflection scanner (110, 222) between a first mode of inspection operation and a second mode of alignment operation, wherein
during the first mode of inspection operation, the operation of first and second deflection scanner (110, 222) is synchronized and adjusted such that the plurality of focus points (15) of secondary particle beamlets (9) is kept on fixed positions at the detector (600), such that each of the secondary beamlets (9) is assigned to and collected by a predetermined set of detection elements (625),
during the second mode of alignment operation, the operation of either the first, the second or both deflection scanners (110, 222) is adjusted such that the plurality of secondary particle beamlets (9) is laterally swept over the detector (600).

Clause 24: The system according to clause 23, wherein, in the second mode of operation, either the first deflection scanner (110) or second deflection scanner (222) is switched off.

Clause 25: The system according to clauses 23 or 24, wherein the control unit (800) is further configured to determine during the second mode of operation a deviation of the third raster configuration (41.3) with respect to the sets of detection elements (625), and wherein the control unit (800) is further configured to adjust the plurality of sets of detection elements (625) or the third raster configuration (41.3).

Clause 26: The system according to clause 25, wherein the secondary electron optical system (200) or the detector (600) further comprise a mechanism for adjusting a scale, a position or a rotation of the third or fourth raster configuration.

Clause 27: The system according to clause 26, wherein the detector (600) comprises a mechanism to adjust scale, position or a rotation of the sets of detection elements (625) to the third raster configuration.

Clause 28: The system according to any of the clauses 23 to 27, wherein a set of detection elements (625) comprises one, four, nine or more detection elements 623.

Clause 29: The system according to clause 28, wherein each of the plurality of sets of detection elements (625) comprises at least two detection elements (623), and wherein the control unit (800) further comprises an image data acquisition unit (810), configured for an integration of the scanning signals of the at least two detection element (623) of a set of detection elements (625) during a recording of a scanning intensity signals (901) for each secondary electron beamlet (9).

Clause 30: The system according to any of the clauses 23 to 29, wherein the detector (600) comprises an electron to light conversion element (602) and an optical relay system (605, 611, 615) configured for an adjustment of a magnification, a displacement, or a rotation of the plurality of light beams.

Clause 31: The system according to clause 30, wherein the detector (600) further comprises an optical zoom system (611) configured for an adjustment of a magnification or scale of the light beams.

Clause 32: The system according to any of the clauses 23 to 29, further comprising a mechanical mechanism for displacing or rotating the fourth raster configuration (41.4).

Clause 33: Method of calibrating a monitoring system of a multi-beam charged particle beam system (1), comprising:
generating a plurality of primary charged particle beamlets (3) in a first raster configuration (41.1),
generating, by irradiation of a surface (25) of an object (7) with the plurality of primary charged particle beamlets (3), a plurality of secondary charged particle beamlets (9),
   forming secondary electron focus spots (15) of the plurality of secondary charged particle beamlets (9) on a detector (600) in a third raster configuration (41.4),
scanning of the secondary electron focus spots (15) over the detector (600) and generating a plurality of scanning intensity signals (901),
determining, from the plurality of scanning intensity signals (901), at least one of a first scale, a first lateral position, or a first rotation of the third raster configuration (41.3);
determining a second scale, a second lateral position, and a second rotation of the focus spots (15) of the plurality of secondary charged particle beamlets (9) with a second monitoring system (230);
matching the second scale, the second lateral position, and the second rotation to the first scale, the first lateral position, and the first rotation.

Clause 34: The method of clause 33, wherein the determining at least one of the first scale, the first lateral position, or the first rotation from the scanning intensity signals (901) comprises at least one of an image processing, a matched filtering, or a machine learning method applied to scanning intensity signals (901).

Clause 35: Method of calibrating a synchronized operation of a first deflection scanner (110) for scanning deflection of a plurality of primary charged particle beamlets (3) and a second deflection scanner (222) for scanning deflection of a plurality of secondary electron beamlets (9) of a multi-beam system (1),
generating a plurality of scanning intensity signal (901) according to any of the clauses 1 to 11, and
determining an offset of the first or the second deflection scanner (110, 222).

Clause 36: The method according to clause 35, further comprising the step of adjusting a deflector offset of either the first or second deflection scanner (110, 222).

A list of reference signs is provided:
1 Multi-beam charged particle system
3 primary beamlets
5 focus spot of primary beamlets in object plane
7 sample or object
9 secondary electron beamlets
15 focus spot of secondary electron beamlets in image plane
25 surface of object
27 pattern structure on surface of object
41 Raster configuration
45 frame of ideal raster configuration
85 apertures
100 primary beam illumination system
101 object plane
102 objective lens
103 field lenses
108 intersection point
110 first scanning deflector
200 secondary electron imaging system
205 imaging lenses
210 secondary electron imaging path
216 multi-aperture array element
222 second scanning deflector
225 image plane of secondary electron imaging system
230 second monitoring system
232 monitoring detector
235 monitoring relay lens
237 monitoring deflector or divider
241 retraction system
300 primary beamlet generation unit
301 charged particle source
303 collector lenses
305 multi-aperture arrangement
306 first multi-aperture plate
307 field lens
308 field lens
309 collimated charged particle beam
321 intermediate image surface
400 beam divider
500 sample stage
503 voltage supply for extraction field
600 detector
602 electron to light converter
605 optical imaging element
607 folding mirror
609 light beam
611 optical zoom
613 image plane of optical relay
615 optical light guide
617 light guide frame
623 detection element
625 set of detection elements
630 movement direction of retractable monitoring system 230
800 control unit
810 image data acquisition unit
820 monitoring control unit
840 adjustment control unit
860 scanning control unit
880 control processor
890 memory
901 scanning image
903 distortion or displacement
905 rotation
907 intensity signal

What is claimed is:

1. A method, comprising:
using a multi-beam charged particle imaging system to generate a plurality of primary charged particle beamlets in a first raster configuration;
irradiating a surface of an object with the plurality of primary charged particle beamlets to generate a plurality of secondary charged particle beamlets;
forming secondary electron focus spots of the plurality of secondary charged particle beamlets in a third raster configuration on a detector;
scanning the secondary electron focus spots over the detector;
recording a plurality of scanning intensity signals; and
determining the third raster configuration from the plurality of scanning intensity signals.

2. The method of claim 1, wherein determining of the third raster configuration comprises:
at least one member selected from the group consisting of image processing of the scanning intensity signals, matched filtering of the scanning intensity signals, and applying a machine learning method to the plurality of scanning intensity signals; and
determining at least one member selected from the group consisting of a scale of the third raster configuration, a lateral position of the third raster configuration, and a rotation of the third raster configuration.

3. The method of claim 1, wherein the detector comprises a plurality of sets of detection elements arranged in a fourth raster configuration, and determining the third raster configuration comprises laterally scanning the secondary electron focus spots over the plurality of sets of detection elements.

4. The method of claim 3, wherein determining the third raster configuration comprises determining a deviation between the third and fourth raster configurations.

5. The method of claim 1, wherein determining the third raster configuration from the scanning intensity signals comprises at least one member selected from the group consisting of image processing the scanning intensity signals, matched filtering the scanning intensity signals, and applying a machine learning method to the scanning intensity signals.

6. The method of claim 1, further comprising determining a telecentricity property of the secondary electron beamlets based on:
i) longitudinally scanning the secondary electron focus spots perpendicular to an image plane in which the detector is disposed, or
ii) defocusing the secondary electron focus spots perpendicular to the image plane in which the detector is arranged.

7. The method of claim 1, wherein the detector comprises a converter in an image plane, the converter is configured to convert the secondary electrons to light, and the secondary electron focus spots are on the converter.

8. The method of claim 1, wherein each set of detection elements comprises at least two detection elements, and recording the plurality of scanning intensity signals integrating the scanning signals of the at least two detection element of a set of detection elements.

9. The method of claim 1, wherein scanning the secondary electron focus spots comprises using a deflection scanner to scan the plurality of primary charged particle beamlets over the object.

10. The method of claim 1, wherein scanning of the secondary electron focus spots comprises using a deflection scanner to scan the plurality of secondary charged particle beamlets.

11. The method of claim 1, wherein scanning the secondary electron focus spots comprises:
i) using a first deflection scanner to scan the plurality of primary charged particle beamlets over the object; and
ii) using a second deflection scanner to scan the plurality of secondary charged particle beamlets.

12. The method of claim 1, further comprising modifying the third raster configuration of the secondary electron focus spots.

13. The method of claim 12, wherein modifying the third raster configuration of the secondary electron focus spots comprises at least one member selected from the group consisting of adjusting an imaging scale of the third raster configuration, adjusting an anamorphism of the third raster configuration, adjusting a displacement of the third raster configuration, and adjusting a rotation of the third raster configuration.

14. The method of claim 12, wherein modifying the third raster configuration of the secondary electron focus spots comprises:
using a converter of the detector to excite a plurality of light beams at the secondary electron focus spots of the plurality of secondary charged particle beamlets; and
using an optical relay system to image the light beams on the detection elements; and
using the optical relay system to adjust a magnification of the light beams, displace the light beams, or rotate the light beams.

15. The method of claim 14, wherein the detector comprises an optical zoom system, and modifying the third raster configuration of the secondary electron focus spots comprises adjusting a magnification of the optical zoom system.

16. The method of claim 12, wherein the detector comprises a plurality of sets of detection elements disposed in a fourth raster configuration, and the method further comprises adjusting the fourth raster configuration of the plurality of sets of detection elements.

17. The method of claim 16, wherein adjusting the fourth raster configuration comprises re-assigning at least one detection element to modify the plurality of sets of detection elements.

18. A method, comprising, comprising:
using a multi-beam charged particle imaging system to generate a plurality of primary charged particle beamlets in a first raster configuration;
irradiating a surface of an object with the plurality of primary charged particle beamlets to generate a plurality of secondary charged particle beamlets in a second raster configuration;
forming secondary electron focus spots of the plurality of secondary charged particle beamlets on a detector in a third raster configuration; and
operating the multi-beam charged particle imaging system to: i) obtain an image of a surface segment of the object; or ii) determine the third raster configuration.

19. A multi-beam charged particle imaging system, comprising:
a multi-beam generator configured to generate a plurality of primary charged particle beamlets in a first raster configuration;
a primary electron optical system configured to generate a plurality of focus spots of the plurality of primary charged particle beamlets on a surface of an object, the primary electron optical system comprising a first deflection scanner;
a beam divider;
a detector comprising a plurality of sets of detection elements in a fourth raster configuration;
a secondary electron optical system configured to generate a plurality of focus spots of secondary electron beamlets in a third raster configuration on the detector, the plurality of secondary charged particle beamlets originating from the focus spots of the plurality of primary charged particle beamlets, the secondary electron optical system comprising a second deflection scanner; and
a controller configured to switch the first and second deflection scanners between an inspection mode of operation and an alignment mode of operation,
wherein:
during the inspection mode of operation, operation of the first and second deflection scanner is synchronized and adjusted so that the plurality of focus points of secondary particle beamlets is kept on fixed positions at the detector so that each secondary beamlet is assigned to and collected by a set of detection elements; and
during the alignment mode of operation, operation of the first deflection scanner and/or the second deflection scanners to laterally sweep the plurality of secondary particle beamlets over the detector.

20. A method, comprising:
using a multi-beam charged particle beam system to generate a plurality of primary charged particle beamlets in a first raster configuration;
irradiating a surface of an object with the plurality of primary charged particle beamlets to generate a plurality of secondary charged particle beamlets;
forming secondary electron focus spots of the plurality of secondary charged particle beamlets on a detector in a third raster configuration;
scanning the secondary electron focus spots over the detector and generating a plurality of scanning intensity signals;
determining, from the plurality of scanning intensity signals, at least one member selected from the group consisting of a first scale of the third raster configuration, a first lateral position of the third raster configuration, and a first rotation of the third raster configuration;
using the monitoring system to determine at least one member selected from the group consisting of a second scale of the focus spots of the plurality of secondary charged particle beamlets, a second lateral position of the focus spots of the plurality of secondary charged particle beamlets, and a second rotation of the focus spots of the plurality of secondary charged particle beamlets; and
matching at least one member selected from the group consisting of: i) the second scale to the first scale; ii) the second lateral position to the first lateral position; and ii) the second rotation to the first rotation.
